(19) United States
(12) Patent Application Publication
(10) Pub. No.: US 2019/0357647 A1
(43) Pub. Date: Nov. 28, 2019

(54) CONSUMER ELECTRONICS DEVICES AND METHODS OF MAKING THE SAME

(71) Applicant: ARCONIC INC., Pittsburgh, PA (US)

(72) Inventors: Raymond J. Kilmer, Pittsburgh, PA (US); Steven B. Leonard, Sarver, PA (US); Lynette Karabin, Ruffs Dale, PA (US); Jennifer L. Giocondi, Pittsburgh, PA (US); Daniel L. Serafin, Baden, PA (US); Philip Gacka, Allison Park, PA (US); Jen C. Lin, Export, PA (US); Leighton M. Cooper, Murrysville, PA (US); Carl E. Garesche, Pittsburgh, PA (US)

(21) Appl. No.: 16/533,358

(22) Filed: Aug. 6, 2019

Related U.S. Application Data
(63) Continuation of application No. PCT/US2018/017106, filed on Feb. 6, 2018.
(60) Provisional application No. 62/458,738, filed on Feb. 14, 2017.
(60) Provisional application No. 62/455,694, filed on Feb. 7, 2017.

(51) Int. Cl. A45C 11/00; B33Y 80/00; B33Y 70/00; A45C 15/00; H04M 1/02; H05K 5/00; H05K 5/02; H05K 7/20; H05K 5/04; H01L 51/52; C09D 11/50; C09D 11/52

(52) U.S. Cl. CPC A45C 11/00; H01M 10/425; B33Y 70/00; A45C 15/00; H04M 1/0279; H05K 5/0017; H05K 5/0234; H05K 7/20409; H05K 5/0243; H05K 5/04; H01L 51/524; H05K 5/0086; C09D 11/50; C09D 11/52; B33Y 80/00

(57) ABSTRACT

The present disclosure relates to consumer electronics devices and use of additive manufacturing. In one embodiment, a consumer electronics case has a body, at least one sidewall extending perimetrically around the body to define an inner case wall and an outer case wall, and at least one additively manufactured component or feature on the body.

### CROSS REFERENCE TO RELATED APPLICATIONS

This application is a continuation of International Patent Application No. PCT/US2018/017106, filed Feb. 6, 2018, which claims benefit of U.S. provisional patent application No. 62/455,694, filed Feb. 7, 2017, and claims benefit of U.S. provisional patent application No. 62/458,738, filed Feb. 14, 2017, each of which is incorporated by reference herein in its entirety.

### FIELD OF THE INVENTION

The present disclosure is directed towards various embodiments of consumer electronics products having one or more additively manufactured feature thereon, and related methods of making the same. More specifically, the present disclosure is directed towards utilizing additive manufacturing in consumer electronics products to configure cases with specifically designed properties and/or unique, complex features which are not feasible through conventional approaches.

### BACKGROUND

Consumer electronic product cases having specifically designed properties and/or unique, complex features are desirable in the consumer electronic product marketplace.

### SUMMARY OF THE INVENTION

In some embodiments, a consumer electronics case includes a body; at least one sidewall attached to and extending perimetrically around the body to define an inner case wall and an outer case wall; and an additively manufactured feature on the body.

In some embodiments, extending perimetrically around comprises a partial enclosure of the body.

In some embodiments, extending perimetrically around comprises a complete encirclement of the body.

In some embodiments, the additively manufactured feature is disposed on the inner case wall.

In some embodiments, the additively manufactured feature is selected from the group consisting of: a. a structural support; b. an electroluminescent ink; c. a conductive ink; d. a component pocket; and e. combinations thereof.

In some embodiments, the conductive ink is selected from the group consisting of Ag, Cu, Ni, Al, Pt, Au, and combinations thereof.

In some embodiments, the conductive ink is an inorganic binder, an organic binders, or a reactive agent.

In some embodiments, the conductive ink is configured onto the body via inkjet printing, a droplet-based process, additively manufacturing via an Optomec additive manufacturing machine, or direct-write assembly.

In some embodiments, the electroluminescent ink is deposited via a binder jet additive manufacturing machine.

In some embodiments, the additively manufactured feature is disposed on the outer case wall.

In some embodiments, the additively manufactured feature disposed on the outer case wall is selected from the group consisting of: a. a structural support; b. a heat sink; c. a tactile grip portion; d. an aesthetic component; e. a stand; f. an attachment device; g. an audio outlet portion; h. a device accessories attachment area; and i. combinations thereof.

In some embodiments, the consumer electronics case is additively manufactured, and wherein the consumer electronics case is configured to accept a non-additively manufactured feature therein, and wherein the non-additively manufactured feature is selected from the group consisting of: a. an electroluminescent ink; b. a conductive ink; c. a device configured to be retained in an additively manufactured component pocket; and d. combinations thereof.

In some embodiments, the consumer electronics case is configured from a metallic material.

In some embodiments, the additively manufactured feature is configured from a metallic additively manufactured material.

In some embodiments, the metallic additively manufactured material is selected from the group consisting of: a. a finishable material; b. a high strength material; c. a thermally conductive material; d. a machineable material; and e. combinations thereof.

In some embodiments, the finishable material comprises: a. an aesthetic visual observation surface, b. a scratch resistant surface, c. a corrosion resistant surface, d. a surface durable to UV; and e. combinations thereof.

In some embodiments, the finishable material comprises an anodizable material configured to provide a surface of the additively manufactured feature ranging from a highly polished finish to a matte finish.

In some embodiments, the anodizable material extends along at least a portion of the inner case wall, such that via the anodizable material the consumer electronics case is configured with an electrically insulating substrate or an electrically insulating surface to configure additional electrical components thereon.

In some embodiments, the finishable material comprises: a high purity aluminum alloy; a matte finish alloy, a 6xxx series aluminum alloy, a 5xxx series aluminum alloy, and combinations thereof.

In some embodiments, the machineable material comprises a 2xxx series aluminum alloy, a 3xxx series aluminum alloy, a 5xxx series aluminum alloys, a 6xxx series aluminum alloy, a 7xxx aluminum alloy, and combinations thereof.

In some embodiments, the high strength material comprises: a. a titanium alloy, b. a 7xxx series aluminum alloy, c. an Al—Li alloy; d. a dispersion strengthened alloy; e. an aluminum based metal matrix composite, and f. combinations thereof.

In some embodiments, at least a portion of the consumer electronics case is additively manufactured.

In some embodiments, the consumer electronics case is non-additively manufactured and has at least one additively manufactured feature configured thereon.

In some embodiments, the additively manufactured feature is configured from a plurality of additively manufacturing feedstocks, wherein the additively manufactured feature is configured in distinct additively manufactured layers or in distinct additively manufactured regions.

In some embodiments, the additive manufacturing feedstock is selected from the group consisting of: a. an aluminum alloy; b. a magnesium alloy; c. a titanium alloy; and d. combinations thereof.

In some embodiments, the additively manufactured feature is configured from a plurality of additively manufactured layers or plurality of additively manufactured regions configured as a gradient from a first layer to a second layer.

In some embodiments, the additively manufactured feature is a localized portion.

In some embodiments, the consumer electronics case is additively manufactured and is configured with a non-additively manufactured feature.

In some embodiments, the non-additively manufactured feature is an antennae.

In some embodiments, the consumer electronics case is configured to hold a portable consumer electronics device.

In some embodiments, the consumer electronics case is additively manufactured with a powder based deposition.

In some embodiments, a consumer electronics case configured from a metallic material, the consumer electronics case includes: a. a body; b. at least one sidewall attached to and extending perimetrically around the body to define an inner case wall and an outer case wall, wherein the inner case wall is configured to define an inner cavity to house a plurality of electronic components; and c. an additively manufactured feature configured on the inner case wall from the metallic material; wherein the additively manufactured feature is a plurality of additively manufactured builds along at least a portion of a length of the inner case wall, and wherein the plurality of additively manufactured builds are configured to provide structural support to at least one of the body and the at least one sidewall.

In some embodiments, the additively manufactured builds configured as a structural support are positioned proximate to a body-to-sidewall edge of the consumer electronics case.

In some embodiments, the additively manufactured builds configured as a structural support are positioned proximate to a sidewall-to-sidewall edge of the case.

In some embodiments, the additively manufactured builds configured as structural support are positioned to extend along the entire inner surface of the case.

In some embodiments, the additively manufactured builds configured as a structural support are positioned to extend along an entire inner surface of the body.

In some embodiments, the additively manufactured builds are configured as: a plurality of raised ridges, with an interspaced configuration.

In some embodiments, the additively manufactured builds are configured as: a grid pattern comprising a plurality of additively manufactured builds, wherein the plurality of additively manufactured builds are intersecting raised lines configured orthogonally to one another.

In some embodiments, the additively manufactured builds are configured to enable attachment of a flexible OLED to the consumer electronics case.

In some embodiments, a consumer electronics case configured from a metallic material, the consumer electronics case includes: a. a body; b. at least one sidewall attached to and extending perimetrically around the body to define an inner case wall and an outer case wall, wherein the inner case wall is configured to define an inner cavity to house a plurality of electronic components; c. a flexible OLED display configured to extend across the inner cavity and communicate with the plurality of electronic components; and d. an additively manufactured feature configured on the inner case wall from the metallic material; wherein the additively manufactured feature is a plurality of additively manufactured builds along the consumer electronics case to provide mechanical attachment of the flexible OLED to the consumer electronics case while permitting the flexible OLED display and corresponding inner case wall to adjust within threshold movement parameters.

In some embodiments, a consumer electronics case configured from a metallic material, the consumer electronics case includes: a. a body; b. at least one sidewall attached to and extending perimetrically around the body to define an inner case wall and an outer case wall, wherein the inner case wall is configured to define an inner cavity to house a plurality of electronic components; c. at least one hole defined in the body and extending from the inner case wall to the outer case wall; d. a coating configured on the outer case wall and extending across the hole defined in the body; and e. a first additively manufactured feature configured on the inner case wall from the metallic material; f. wherein the first additively manufactured feature is an electroluminescent ink that is additively deposited in the hole along an inner surface of the coating; and g. a second additively manufactured feature on the inner case wall configured as a conductive ink configured between the electroluminescent ink and a power source.

In some embodiments, an electrical insulator is positioned between the inner case wall and the conductive ink.

In some embodiments, the electrical insulator is selected from the group consisting of: ceramics, glass, polymer, and combinations thereof.

In some embodiments, the electrical insulator is additively manufactured in place on the consumer electronics case.

In some embodiments, the electrical insulator is deposited via painting, spraying, coating, and combinations thereof.

In some embodiments, the electroluminescent ink is selected from the group consisting of: an irradiated polymer coating; electrochromic polymers, electronic ink, electrophoretic displays, and combinations thereof.

In some embodiments, the coating is a clear coating.

In some embodiments, the coating is a translucent coating configured to transmit light.

In some embodiments, the coating is an opaque coating.

In some embodiments, the clear coating is selected from the group consisting of: acrylics, epoxys, polyesters, polyurethanes, fluoropolymers, silozanes, siloxanes, and combinations thereof.

In some embodiments, the translucent coating is selected from the group consisting of: acrylics, epoxys, polyesters, polyurethanes, fluoropolymers, silozanes, siloxanes, and combinations thereof.

In some embodiments, the opaque coating is selected from the group consisting of: acrylics, epoxys, polyesters, polyurethanes, fluoropolymers, silozanes, siloxanes, and combinations thereof.

In some embodiments, a consumer electronics case configured from a metallic material, the consumer electronics case having: a. a body; b. at least one sidewall attached to and extending perimetrically around the body to define an inner case wall and an outer case wall, wherein the inner case wall is configured to define an inner cavity to house a plurality of electronic components; c. at least one hole defined in the body and extending from the inner case wall to the outer case wall; d. a coating configured on the outer case wall and extending across the hole defined in the body; and e. an electroluminescent ink positioned on an inner sidewall of the coating and extending across a surface of the coating to fill in the hole; and f. an additively manufactured feature on the inner case wall, wherein the additively manufactured feature is a conductive ink configured between the electroluminescent ink and a power source.

In some embodiments, a consumer electronics case configured from a metallic material, the consumer electronics case having: a. a body; b. at least one sidewall attached to and extending perimetrically around the body to define an inner case wall and an outer case wall, wherein the inner case wall is configured to define an inner cavity to house a plurality of electronic components; c. an electrical insulator material positioned along at least a portion of the inner side wall of the body and extending across at least a portion of the inner surface of the body; and d. an additively manufactured feature comprising a conductive ink, wherein the conductive ink is configured to provide an additively manufactured antenna, wherein the additively manufactured antenna is positioned onto the electrical insulator material and configured to be in electrical communication with a power source.

In some embodiments, a consumer electronics case configured from a metallic material, the consumer electronics case having: a. a body; b. at least one sidewall attached to and extending perimetrically around the body to define an inner case wall and an outer case wall, wherein the inner case wall is configured to define an inner cavity to house a plurality of electronic components; c. an electrical insulator material positioned along at least a portion of the inner side wall of the body and extending across at least a portion of the inner surface of the body ; and d. an additively manufactured feature comprising a conductive ink, wherein the conductive ink is configured to provide a additively manufactured printed circuit, wherein the additively manufactured printed circuit is positioned onto the electrical insulator material and configured to be in electrical communication with a power source.

In some embodiments, a consumer electronics case configured from a metallic material, the consumer electronics case having: a. a body; b. at least one sidewall attached to and extending perimetrically around the body to define an inner case wall and an outer case wall, wherein the inner case wall is configured to define an inner cavity to house a plurality of electronic components; and c. an additively manufactured feature comprising a component pocket defined by an additively manufactured build to define the component pocket, wherein the component pocket is configured to accept a device selected from the group consisting of: i. a magnet; a power source, a circuit board, and combinations thereof.

In some embodiments, a consumer electronics case configured from a metallic material, the consumer electronics case having: a. a body; b. at least one sidewall attached to and extending perimetrically around the body to define an inner case wall and an outer case wall, wherein the inner case wall is configured to define an inner cavity to house a plurality of electronic components; and c. an additively manufactured feature configured on the outer case wall from the metallic material; wherein the additively manufactured feature is a plurality of additively manufactured builds along at least a portion of a length of the outer sidewall, wherein the plurality of additively manufactured builds are configured to provide at least one of: a structural support to the case; a structural support to the body; a structural support to the sidewall; a structural support to the sidewall-to-sidewall edge; a structural support to the sidewall-to-body edge; a stand; a tactile grip configured for user interface; an aesthetic pattern; a heat sink; and combinations thereof.

In some embodiments, a consumer electronics case configured from a metallic material, the consumer electronics case having: a. a body; b. at least one sidewall attached to and extending perimetrically around the body to define an inner case wall and an outer case wall, wherein the inner case wall is configured to define an inner cavity to house a plurality of electronic components; and c. an additively manufactured feature configured on the outer case wall from the metallic material; wherein the additively manufactured feature is a plurality of additively manufactured builds along at least a portion of the length of the outer sidewall, wherein the plurality of additively manufactured builds are configured to provide at least one of: a structural support to the case, the body, the sidewall, and combinations thereof; a structural support to the edges of the case; a tactile grip configured for user interface; a stand; an aesthetic pattern; a heat sink configured to dissipate heat generated by the device; and combinations thereof.

In some embodiments, the additively manufactured builds are configured proximate to a body-to-sidewall edge of the outer sidewall of the case.

In some embodiments, the additively manufactured builds are configured proximate to a sidewall-to-sidewall edge of the outer sidewall of the case.

In some embodiments, the additively manufactured builds are configured to extend along an entire outer surface of the case.

In some embodiments, the additively manufactured builds are configured to extend along the entire outer surface of the body.

In some embodiments, the additively manufactured builds are configured as: a plurality of raised ridges, with an interspaced configuration.

In some embodiments, the AM builds are configured as: a grid pattern comprising a plurality of additively manufactured builds that are intersecting raised lines configured acute, orthogonal, or obtuse to one another.

In some embodiments, the additively manufactured builds are configured as: a plurality of raised ridges, with an interspaced configuration in a sunburst pattern.

In some embodiments, the additively manufactured builds are configured as polygonal shapes, geometric shapes, asymmetrical patterns, symmetrical patterns, and combinations thereof.

In some embodiments, the additively manufactured builds are configured as: a plurality of circles, with an interspaced configuration.

In some embodiments, the additively manufactured builds are configured as: a plurality of circles, with an interspaced, overlapping, or combinations configuration.

In some embodiments, the additively manufactured builds are configured as: a plurality of circles, with an interspaced concentric configuration.

In some embodiments, the additively manufactured builds are configured as: a plurality of raised ridges with interspaced positioning, wherein the ridges generally correspond to a user's biometric data.

In some embodiments, an additively manufactured build on the case is configured to extend in an outward direction from the case profile.

In some embodiments, the case is configured as: an additively manufactured case having at least one grip portion configured on the case and extending generally to extend in an outward direction from the case profile.

In some embodiments, the stand is configured to extend from the sidewall at an angle, such that the angled surface of the stand is configured to sit on a generally flat surface and retain the case in a corresponding angled vertical position.

In some embodiments, the stand is configured to extend from the sidewall at an angle, such that the angled surface of the stand is configured to sit on a generally flat surface and retain the case in a corresponding angled vertical position, further wherein a portion of the stand that interfaces with the generally flat surface is configured with frictional members to promote static friction between the stand and the generally flat surface.

In some embodiments, the stand is configured to extend from the sidewall at a stepped angle configuration, such that the plurality of angled surfaces enables the stand to sit on a generally flat surface at a corresponding angles to the plurality of angles on the stand, such that the case is retained in a corresponding plurality of angled vertical position.

In some embodiments, the stand is configured as at least one integral foot on the case, such that via the stand, the device is configured to stand up to allow hands free viewing and/or use of device components.

In some embodiments, a consumer electronics case configured from a metallic material, the consumer electronics case having: a. a body: b. at least one sidewall attached to and extending perimetrically around the body to define an inner case wall and an outer case wall, wherein the inner case wall is configured to define an inner cavity to house a plurality of electronic components; and c. an additively manufactured feature configured on the outer case wall, wherein the additively manufactured feature is a metallic material; wherein the additively manufactured feature is an attachment device configured to accept a device stand, a camera module, an ear bud attachment device, and combinations thereof.

In some embodiments, a consumer electronics case configured from a metallic material, the consumer electronics case having: a. a body; b. at least one sidewall attached to and extending perimetrically around the body to define an inner case wall and an outer case wall, wherein the inner case wall is configured to define an inner cavity to house a plurality of electronic components; and c. an additively manufactured feature configured on the outer case wall, wherein the additively manufactured feature is a metallic material; wherein the additively manufactured feature is an audio outlet component configured to accommodate at least one speaker.

In some embodiments, a consumer electronics case is configured from a metallic material, the consumer electronics case having: a. a body; b. at least one sidewall attached to and extending perimetrically around the body to define an inner case wall and an outer case wall, wherein the inner case wall is configured to define an inner cavity to house a plurality of electronic components; and c. an additively manufactured feature configured on the outer case wall, wherein the additively manufactured feature is a metallic material; wherein the additively manufactured feature is an integrated receptacle configured to accept a biological sample, wherein the receptacle is equipped with a sensor for analyzing the sample.

In some embodiments, the case is configured with a door to enclose the inner cavity.

In some embodiments, a consumer electronics case configured from a metallic material, the consumer electronics case having a plurality of layers or a plurality of regions selected from the group consisting of: a. an anodizable material; b. a high strength material; c. a thermally conductive material; d. machineable material; and e. combinations thereof; wherein the case is configured as a body and at least one sidewall attached to and extending perimetrically around the body to define an inner case wall and an outer case wall, wherein the inner case wall is configured to define an inner cavity to house a plurality of electronic components.

In some embodiments, a method, includes: a. providing a consumer electronics case having a body and at least one sidewall attached to and extending perimetrically around the body to define an inner case wall and an outer case wall, wherein the inner case wall is configured to define an inner cavity to house a plurality of electronic components; b. additively manufacturing an additively manufactured component onto the outer case wall, wherein the additively manufactured component is selected from the group consisting of a finishable material; a high strength material; a thermally conductive material; a machineable material; and combinations thereof.

In some embodiments, a method, includes: a. providing a consumer electronics case having a body and at least one sidewall attached to and extending perimetrically around the body to define an inner case wall and an outer case wall, wherein the inner case wall is configured to define an inner cavity to house a plurality of electronic components; b. additively manufacturing an additively manufactured component onto the inner case wall, the additively manufactured component selected from the group consisting of: a finishable material; a high strength material; a thermally conductive material; a machineable material; and combinations thereof.

In some embodiments, a method, includes: selecting features to incorporate onto a consumer electronics device; additively manufacturing a metallic additively manufacturing feedstock onto a metallic consumer electronics case to define at least one additively manufactured component on the metallic consumer electronics case, wherein the at least one additively manufactured components is an at least one outer additively manufactured component or an at least one inner additively manufactured component.

In some embodiments, the outer additively manufactured components configured as geometric shapes, polymeric shapes, and/or patterns are configured as the same size and equidistant/uniform spacing

In some embodiments, the outer additively manufactured components configured as geometric shapes, polymeric shapes, and/or patterns are configured as the same size and non-uniform spacing.

In some embodiments, the outer additively manufactured components configured as geometric shapes, polymeric shapes, and/or patterns are configured as different size and equidistant/uniform spacing.

In some embodiments, the outer additively manufactured components configured as geometric shapes, polymeric shapes, and/or patterns are configured as the different sizes and non-uniform spacing.

In some embodiments, the inner additively manufactured components configured as geometric shapes, polymeric shapes, and/or patterns are configured as the same size and equidistant/uniform spacing.

In some embodiments, the inner additively manufactured components configured as geometric shapes, polymeric shapes, and/or patterns are configured as the same size and non-uniform spacing.

In some embodiments, the inner additively manufactured components configured as geometric shapes, polymeric shapes, and/or patterns are configured as different size and equidistant/uniform spacing.

In some embodiments, the inner additively manufactured components configured as geometric shapes, polymeric shapes, and/or patterns are configured as the different sizes and non-uniform spacing

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments

FIG. 1A provides a schematic view of an embodiment of the instant disclosure which depicts an additively manufactured (AM) case (e.g. body and sidewall) with at least one AM component thereon. In some embodiments, the at least one AM component is positioned on the inside of the case, the outside of the case, within the case, or a combination thereof, in accordance with the instant disclosure. In this embodiment, the case is manufactured via an AM route and incorporates one or more of the AM components referenced herein onto the case. In some embodiments, one or more of the AM components referenced herein are incorporated to the inner side wall, outer sidewall, through the side wall, or a combination thereof to create a consumer electronics case having integral metallic features.

FIG. 1B provides a schematic view of an embodiment of the instant disclosure which depicts a partially additively manufactured case with at least one AM component thereon, in accordance with the instant disclosure. In some embodiments, the partially additively manufactured case has a sidewall with a body additively manufactured thereto. In some embodiments, the at least one AM component is positioned on the inside of the case, the outside of the case, within the case, or a combination thereof. In this embodiment, the case is partially manufactured via an AM route and incorporates one or more of the AM components referenced herein onto the case (i.e. to the inner side wall, outer sidewall, through the side wall, or a combination thereof) to create a consumer electronics case having integral metallic features.

FIG. 1C provides a schematic view of an embodiment of the instant disclosure which depicts a partially additively manufactured case with at least one AM component thereon (e.g. positioned on the inside of the case, the outside of the case, within the case, and/or a combination thereof), in accordance with the instant disclosure. In some embodiments, the partially additively manufactured case has a body with a sidewall additively manufactured thereto. In some embodiments, the at least one AM component is positioned on the inside of the case, the outside of the case, within the case, or a combination thereof. In this embodiment, the case is partially manufactured via an AM route and incorporates one or more of the AM components referenced herein onto the case (i.e. to the inner side wall, outer sidewall, through the side wall, or a combination thereof) to create a consumer electronics case having integral metallic features.

FIG. 1D provides a schematic view of an embodiment of the instant disclosure which depicts a case, with at least one AM component thereon (e.g. positioned on the inside of the case, the outside of the case, within the case, and/or a combination thereof), in accordance with the instant disclosure. In some embodiments, the case has a body with a sidewall, formed without additive manufacturing. In some embodiments, the at least one AM component is positioned on the inside of the case, the outside of the case, within the case, or a combination thereof. In this embodiment, the case is not additively manufactured, instead the case is manufactured via conventional routes, and incorporates one or more of the AM components referenced herein onto the case (i.e. to the inner side wall, outer sidewall, through the side wall, or a combination thereof) to create a consumer electronics case having integral metallic features.

FIG. 2A provides a perspective side view of an embodiment of a case having an AM surface feature configured on the outer surface of the body and sidewalls of the case, in accordance with the instant disclosure. As depicted in FIG. 2A, the raised ridges on the case are configured in a sunburst-like pattern that extend radially from a lower portion of the case, spreading across the body and around the edges of the case to extend onto a portion of the sidewall. The ridges initiate adjacent to each other proximate the central area of the bottom of the body towards the body-to-sidewall edge and extend outwardly from one another towards the other body-to-sidewall edges on the perimetrical sidewall. In this embodiment, the raised ridges are configured in an aesthetic, tactile grip configuration.

FIG. 2B provides a perspective side view of an embodiment of the case of FIG. 2A, showing the inner sidewall of the case configured with a plurality of raised ridges configured as intersecting lines to form a raised grid pattern on the inside sidewall of the case, in accordance with the instant disclosure. In this embodiment, the raised grid pattern is configured to provide structural support and mechanical strength to the case, including the body, sidewall, respective edges, or combinations thereof. As shown in FIG. 2B, the inner AM component 50 on the inner sidewall 32 is configured as raised AM portions 48 in an inner structural support feature 52, in accordance with the instant disclosure.

FIG. 2C provides a cut away side view of the embodiment of the case 10 depicted in FIG. 2A and FIG. 2B, illustrating the AM components 34 configured on the outer case wall 22 (i.e. raised ridges in a sunburst pattern) and on the inner case wall 24 (i.e. raised grid for an inner structural support feature 52), in accordance with the instant disclosure. In this embodiment, the AM components 34 configured on the outer case wall 22 are raised ridges in a sunburst pattern and the AM components 34 configured on the inner case wall 24 is a raised grid for an inner structural support feature 52.

FIGS. 3A-3D depict alternative embodiments of AM surface features 34 configured on the outer case wall 22 as raised AM portion 48 ridges.

FIG. 3A depicts a top plan view of an embodiment of a consumer electronics case illustrating the outer body wall 30 having a series of AM outer features 60 configured as parallel lines with a spaced configuration, in accordance with the instant disclosure. In some embodiments, the parallel lines are raised ridges. As shown in FIG. 3A, the raised ridges extend in a generally parallel direction with opposing edges of the body-to-sidewall edge.

FIG. 3B depicts a top plan view of an embodiment of a consumer electronics case illustrating the outer body wall 30 having a series of AM outer features 60 configured as parallel lines with a spaced configuration, in accordance with the instant disclosure. In some embodiments, the parallel lines are raised ridges. As shown in FIG. 3B, the raised ridges extend in a generally parallel direction in a transverse configuration across the case, generally angled across the outer body wall from one body-to-sidewall edge to the opposing body-to-sidewall edge.

FIG. 3C depicts a top plan view of an embodiment of a consumer electronics case illustrating the outer body wall 30 having a series of AM outer features 60 configured as a tire tread pattern, in accordance with the instant disclosure. As shown in FIG. 3C, the raised ridges are configured as a plurality of intersecting lines that are discontinuous adjacent to points of intersection, where the lines are oriented in a spaced, parallel and perpendicular configuration from one another.

FIG. 3D depicts a top plan view of an embodiment of a consumer electronics case illustrating the outer body wall 30 having a series of AM outer features 60 configured as a plurality of spaced, undulating grooves, in accordance with the instant disclosure. As shown in FIG. 3D, this embodiment utilizes additive manufacturing to create a plurality of ridges having a generally planar configuration (plateaus) with grooves extending down into the case sidewall and terminating with arcuate ends, in accordance with the instant disclosure.

FIGS. 4A-4C depict various views of another embodiment of the instant disclosure.

FIG. 4A depicts a perspective view of the outer case wall 22 which is configured to include outer AM components 60, in accordance with the instant disclosure. In FIG. 4A, the outer AM component 60 is a plurality of ultrafine heat sink 62 ribs (e.g. raised projections on the case outer wall 22), which extend generally parallel across the outer wall 22 and extend from a location along one sidewall 14 portion, over the body-to-sidewall edges 18 and body 12 to a location on the generally opposing sidewall 14 portion.

FIG. 4B provides a cut-away side view of the embodiment depicted in FIG. 4A, depicting the placement of a thermally conductive material 102 (e.g. a graphite sheet) being generally deposited within the body 12 between the outer body wall 30 and inner body wall 32. As generally depicted in FIG. 4B, the thermally conductive material 102 is configured as a non-AM component 110 that is attached to the inner body wall 32 by additively manufacturing at least one additional build layer over at least the perimeter portion (i.e. outer edge) of the thermally conductive material/sheet 102, in accordance with the instant disclosure. Thus, in this configuration the thermally conductive material is configured to absorb heat from the electrical components within the consumer electronics device and transmit the thermal energy (i.e. heat) through the outer body wall 32 to be dissipated via the outer AM component 60 (e.g. ultrafine heat sink ribs).

FIG. 4C depicts a perspective view of FIG. 4B, further illustrating the attachment of the thermal conducting material 102 into the inner body wall 32 via additive manufacturing modes including powder bed or e-beam deposition, in accordance with the instant disclosure.

FIGS. 5A-5C depict various embodiments of outer AM components 60 configured on a consumer electronics case 10, in accordance with the instant disclosure.

FIG. 5A depicts a perspective view of the case 10, showing the outer case wall 22 configured with a plurality of outer AM components, in accordance with the instant disclosure. As shown in FIG. 5A, the outer AM components are a plurality of raised dots configured to provide a tactile grip, a visually observable aesthetic pattern to the outer case wall 22, or a combination thereof. As shown in FIG. 5A, the dots are configured to be the same size and are uniformly and/or equidistantly interspaced.

FIG. 5B depicts a perspective view of the case 10, showing the outer case wall 22 configured with a plurality of outer AM components, in accordance with the instant disclosure. As shown in FIG. 5B, the outer AM components are a plurality of raised dots configured to provide a tactile grip, a visually observable aesthetic pattern to the outer case wall 22, or a combination thereof. As shown in FIG. 5B, the dots are configured to be the same size and are non-uniformly spaced, such that the dots are concentrated in the area adjacent to two generally opposed sidewall-to-body edges and configured on the body. Also, in contrast, the dots of FIG. 5B are a smaller size than those of FIG. 5A.

FIG. 5C depicts a perspective view of the case 10, showing the outer case wall 22 configured with a plurality of outer AM components, in accordance with the instant disclosure. As shown in FIG. 5C, the outer AM components are a plurality of raised dots configured to provide a tactile grip, or a visually observable aesthetic pattern to the outer case wall 22, or a combination thereof. As shown in FIG. 5B, the dots are configured to be the same size and a mixed configuration providing portions of the body with uniformly spaced dots and other portions with either no dots or non-uniformly spaced dots. Also, in contrast, the dots of FIG. 5C are a smaller size than those of FIG. 5A.

FIG. 5D provides a partial cut-away side view of FIG. 5C, depicting the outer AM components 60 amount of extension above (i.e. away) from the normal surface of the outer case wall 22, in accordance with the instant disclosure.

FIGS. 6A-6C depict still another embodiment of the case 22 having an outer AM component 60 thereon, in accordance with the instant disclosure.

FIG. 6A depicts a partial perspective view of a case having a plurality of outer AM components configured as heat sink/dissipation projections, wherein the surface created by the outer AM components has a large plurality of very small, uniform features sufficiently designed and/or configured as a heat sink, in accordance with the instant disclosure.

FIG. 6B depicts a partial plan view of the case 22 of FIG. 6A, but having a discontinuous region defined by areas without the uniform surface projections (e.g. outer AM components 60), thus creating a logo or graphic (e.g. aesthetic component 68) in the outer case wall 22, through the combined effect of outer AM components (e.g. in the form of AM surface projections) adjacent to areas without AM surface projections, in accordance with the instant disclosure.

FIG. 6C depicts a partial cut-away side view of the embodiment of 6A, showing the plurality of surface projections that are together configured as a heat sink 62, in accordance with the instant disclosure.

FIG. 7A depicts a perspective view of a consumer electronics device having a case with AM components, in accordance with the instant disclosure. FIG. 7A depicts several different outer AM components 60 on the case, including: (a) two generally opposing portions of the case 10 having AM builds (e.g. outer AM components 60) that are configured for biometric compatibility with the human hand/grip to provide a grip area 64; (b) a plurality of raised ridges configured to extend generally around the perimeter of the sidewall 14 of the case (e.g. to provide non-slip along a surface or when positioned in a hand); (c) a plurality of raised ridges configured in a parallel pattern and positioned along the outer body wall of the hand grip portion 64 to provide non-slip grip to a surface or hand and to extend generally around the perimeter of the sidewall 14 of the case (e.g. to provide non-skid along a surface or non-slip when positioned in a hand) and an outer AM component configured with a user holding an embodiment of a case 22 having an outer AM component 60 in accordance with the instant disclosure. As visually observed from FIG. 7A, the resulting case 10 has dimensions differing from conventional consumer electronics devices (i.e. non-rectangular, non-planar surfaces) since the dimensions of the outer case wall are integral features configured via additive manufacturing.

FIG. 7B depicts a user holding an embodiment of a case 22 having an outer AM component 60 in accordance with the instant disclosure.

FIG. 8 depicts a plan view of an outer body wall of a case having at least one AM component, in accordance with the instant disclosure. As shown in FIG. 8, a portion of the outer body wall 22 of the case 10 is configured with the tire tread pattern depicted and described in FIG. 3C. Also, the dimensions (e.g. outer perimeter of the mid-region) of the case 10 is configured with (a) a raised arcuate or curved region along one sidewall-to-edge area that is configured to generally rest in the fold of a user's palm/hand and (b) a plurality of ringer grips, defined by a groove in the of the outer perimeter of the when the user is gripping the device.

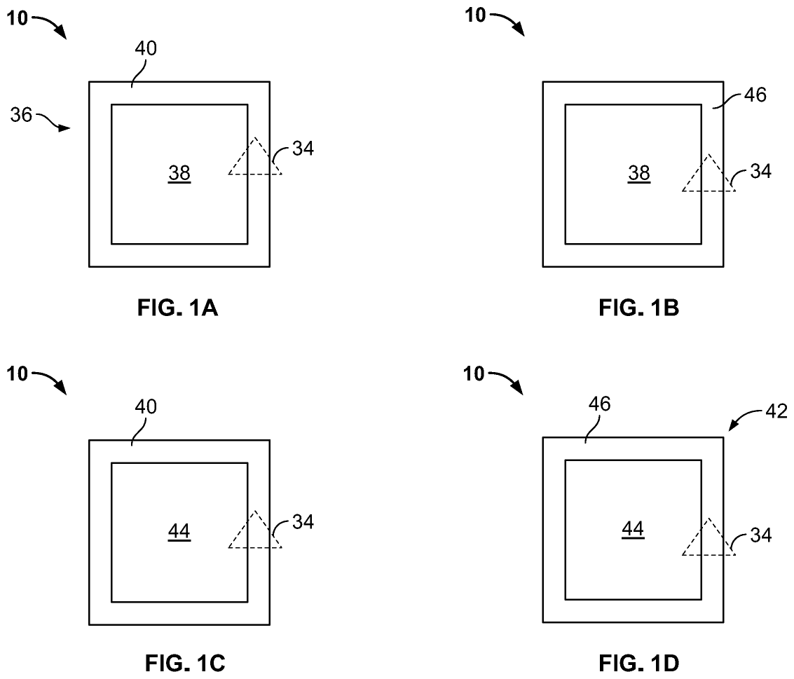

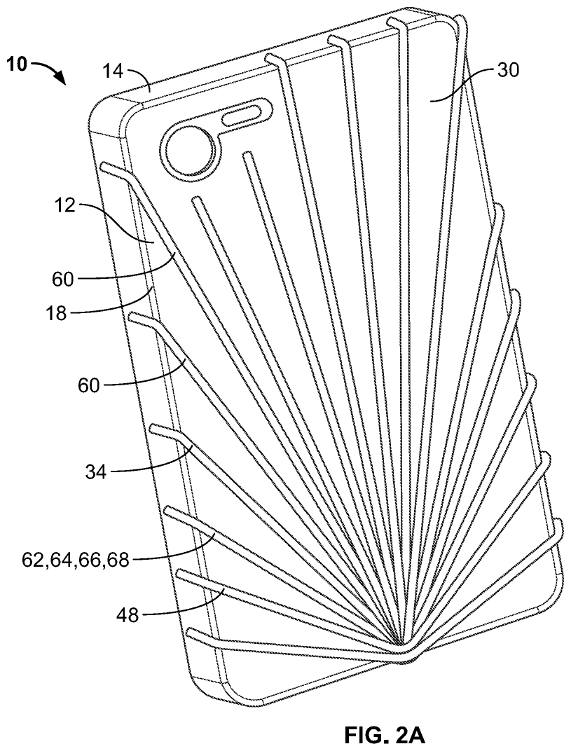

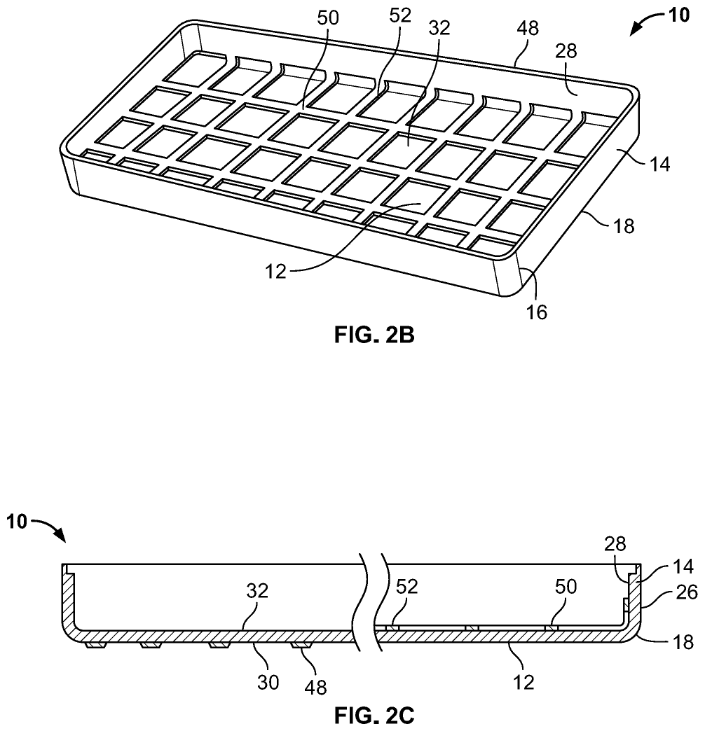

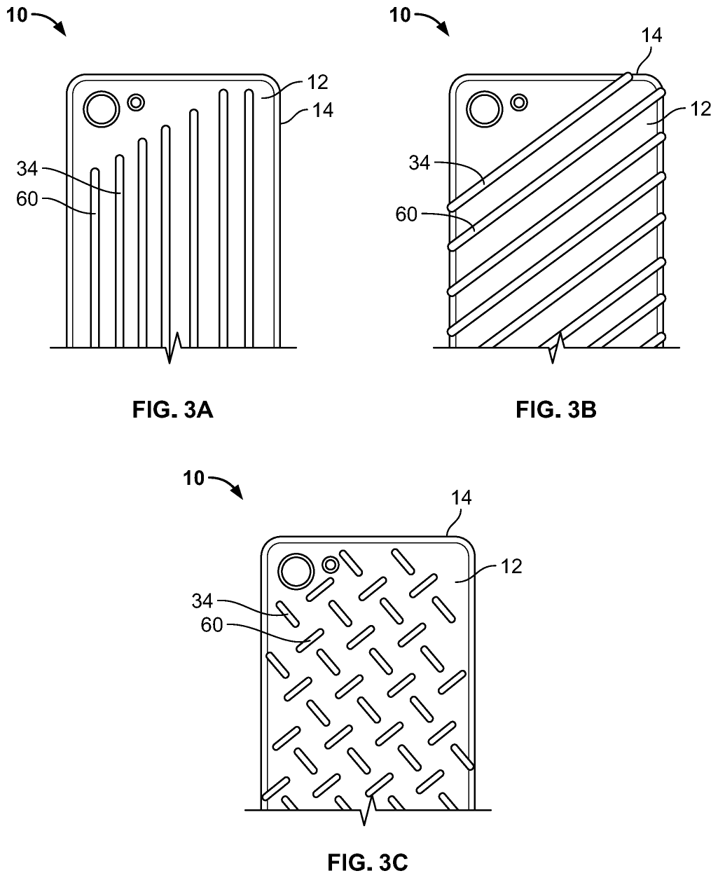

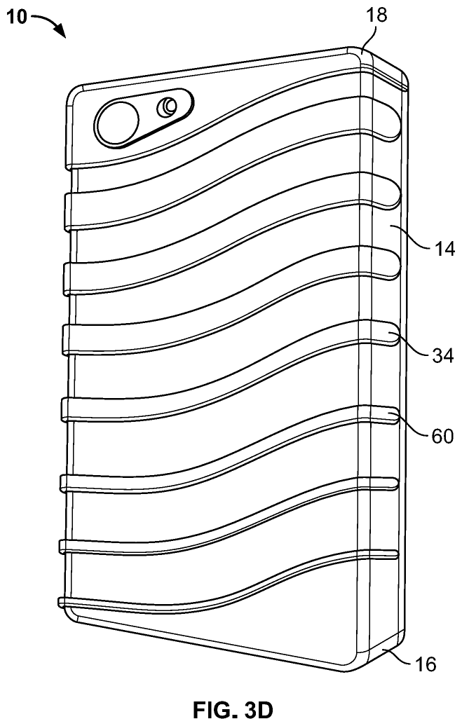

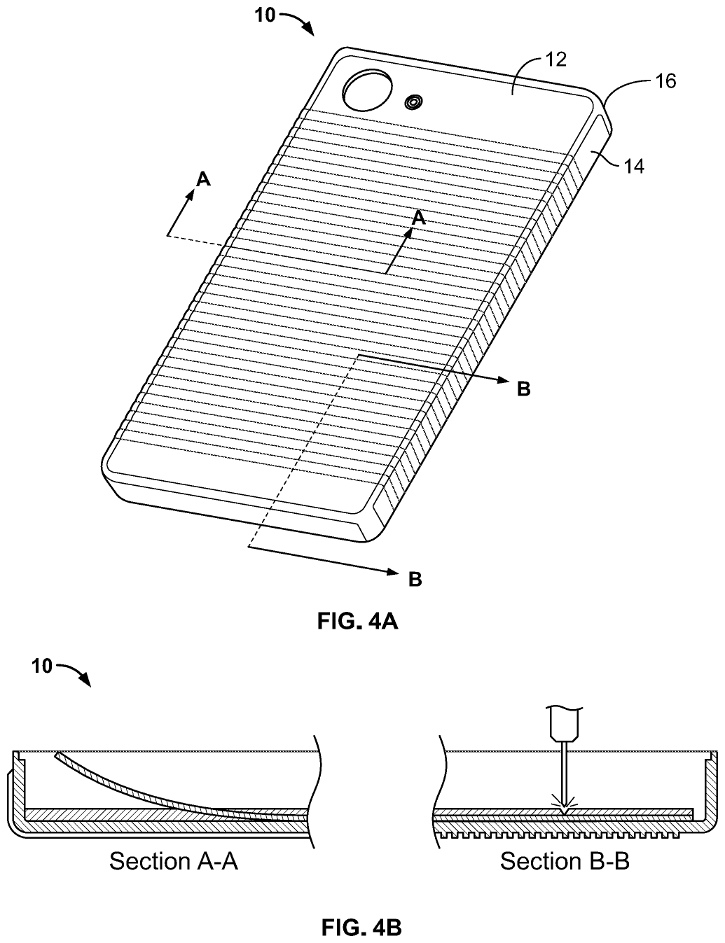

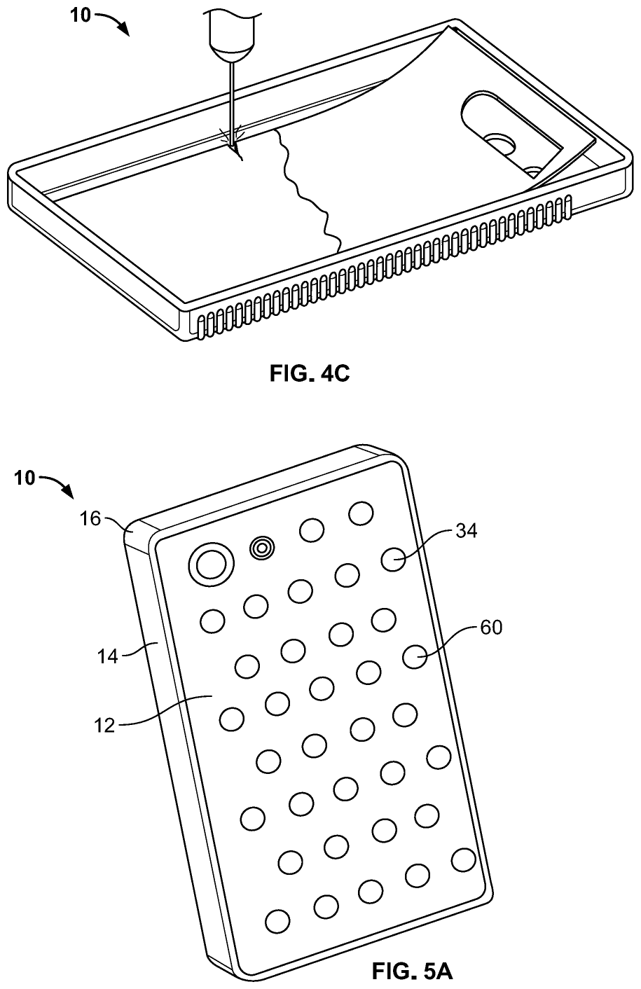

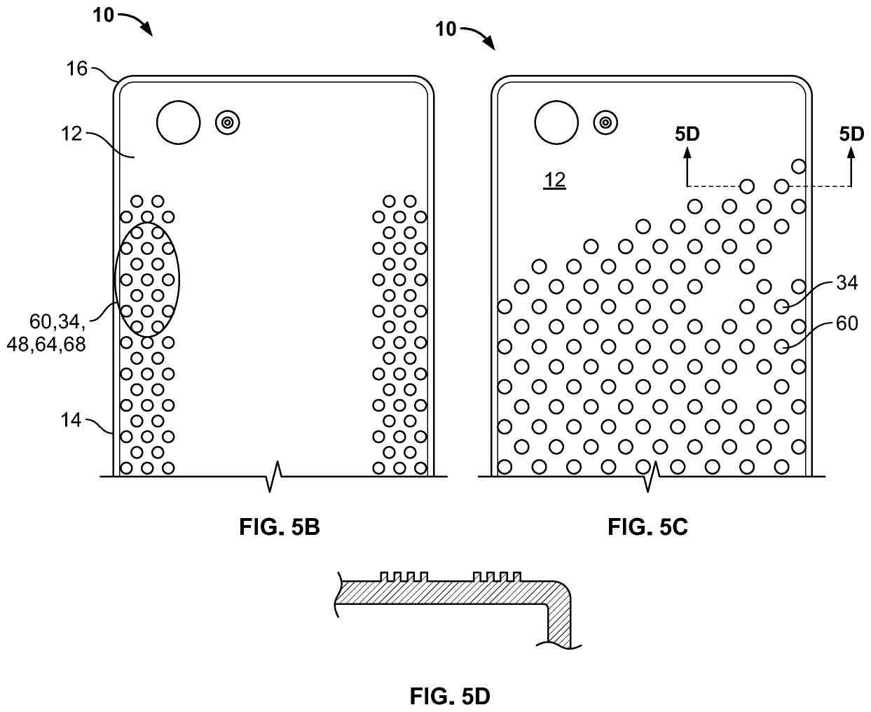

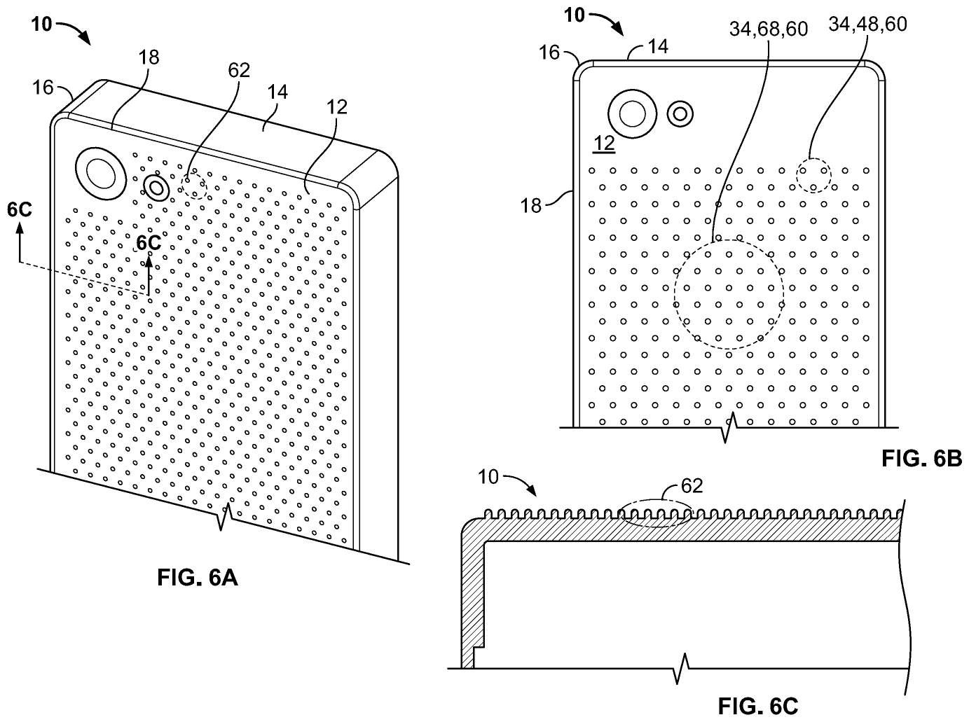

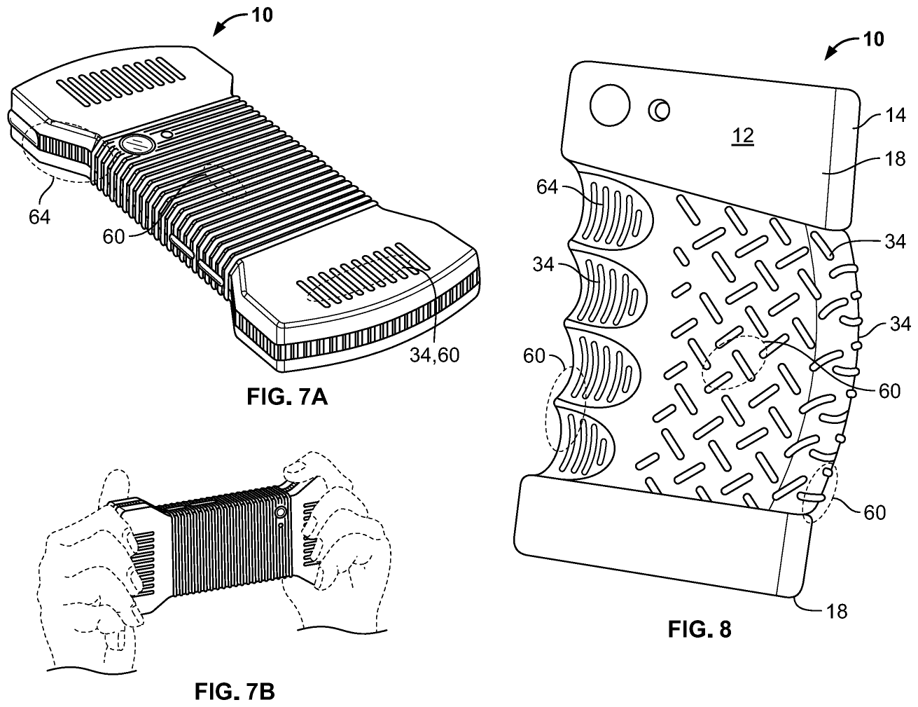

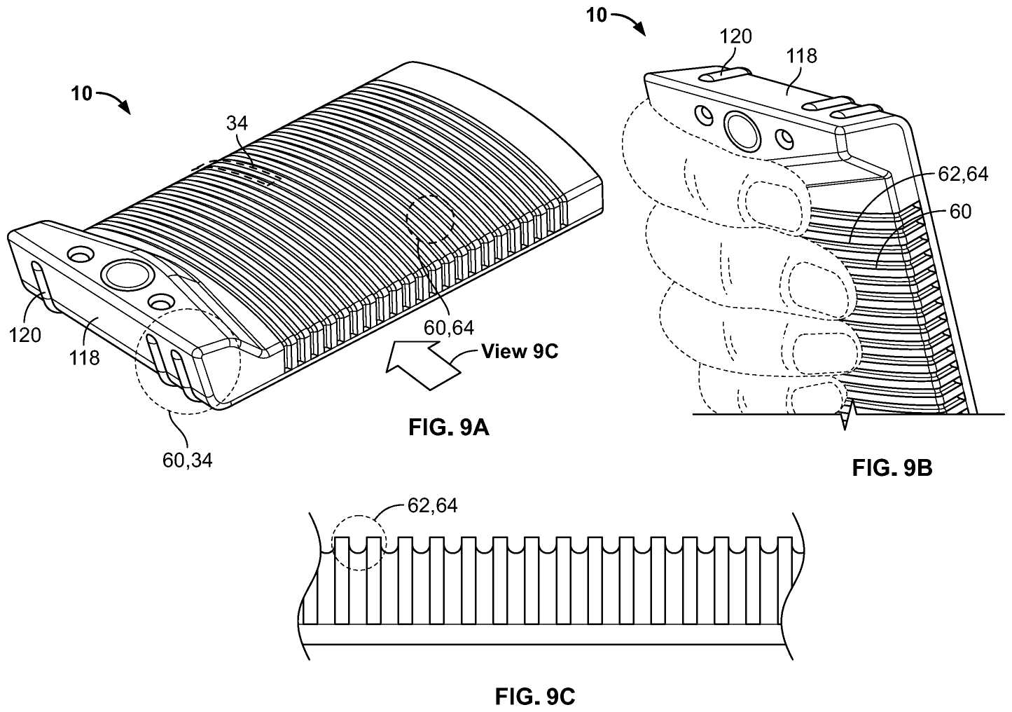

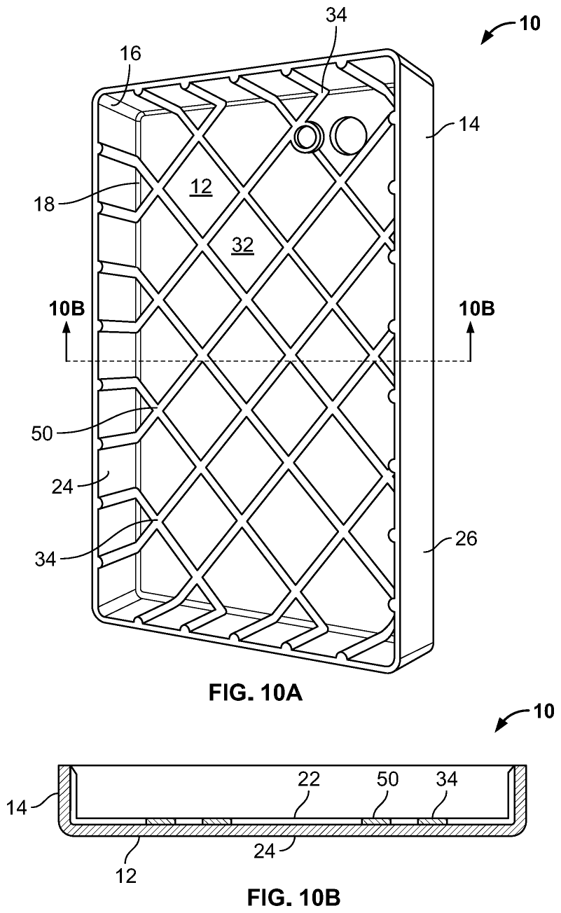

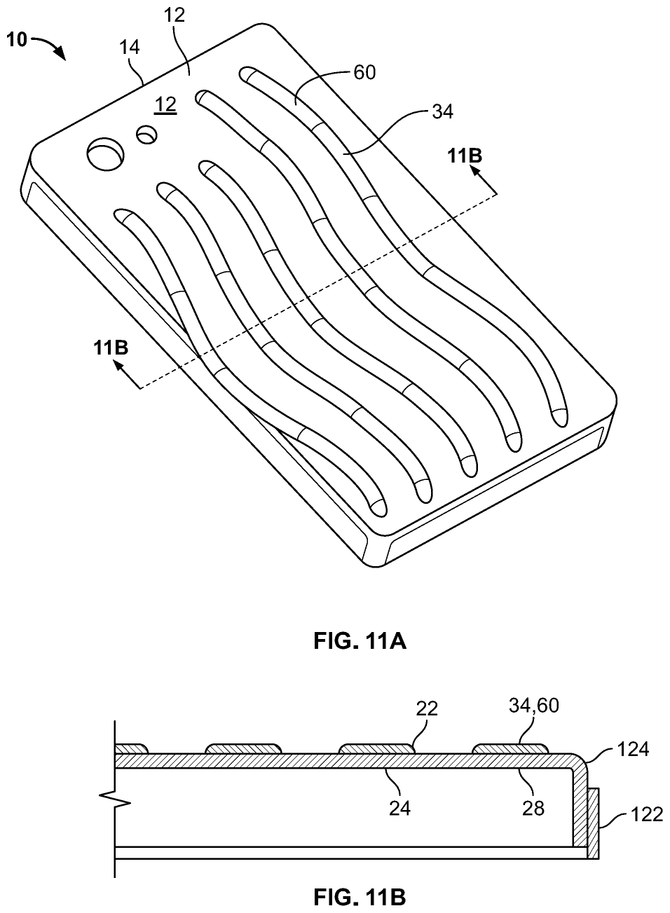

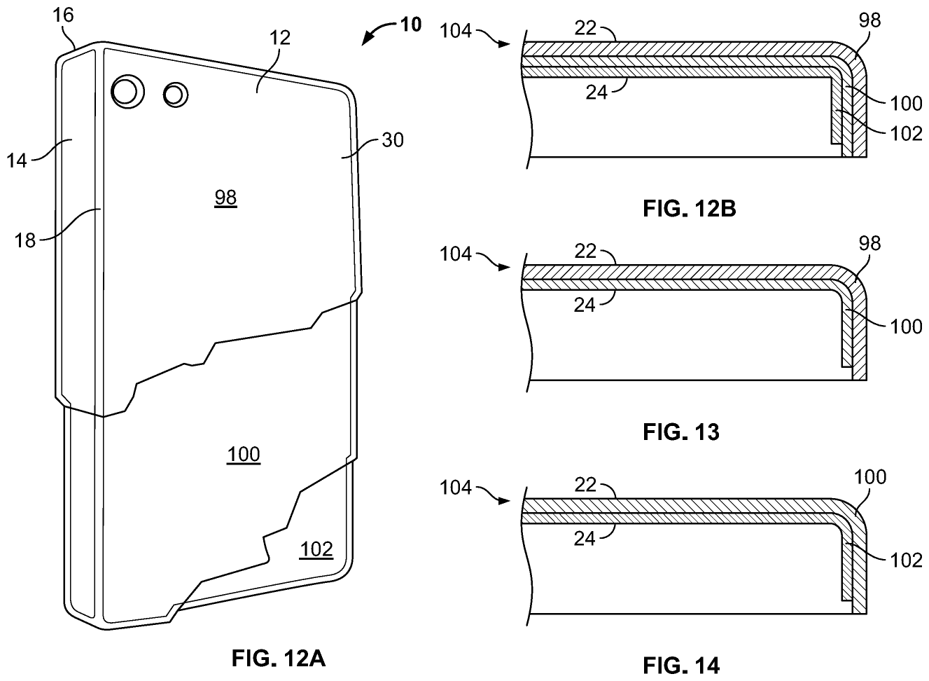

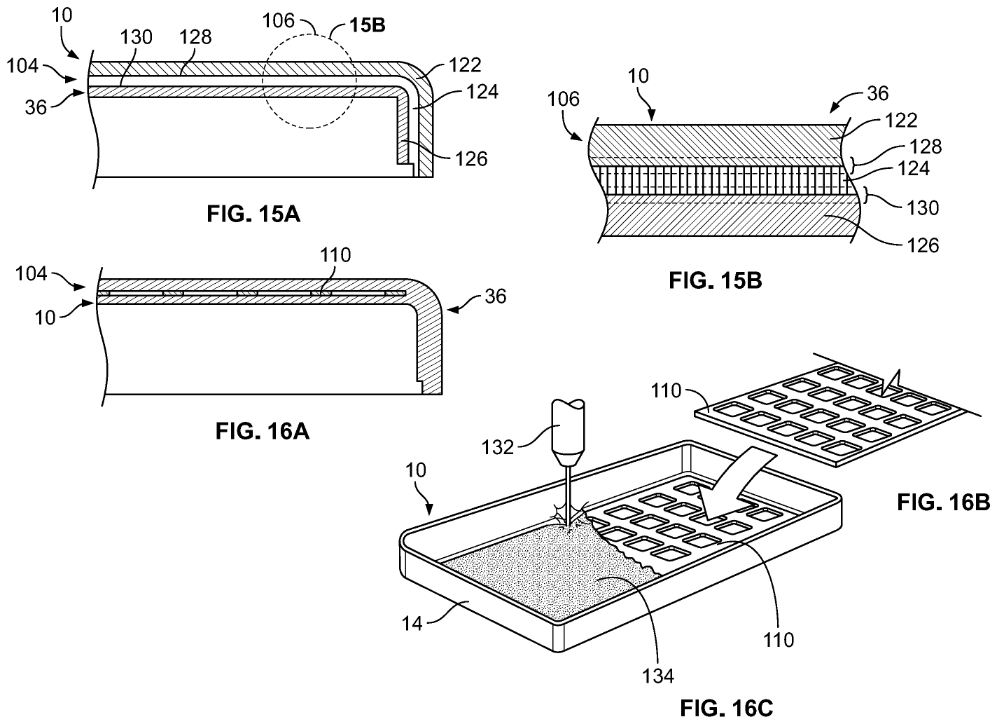

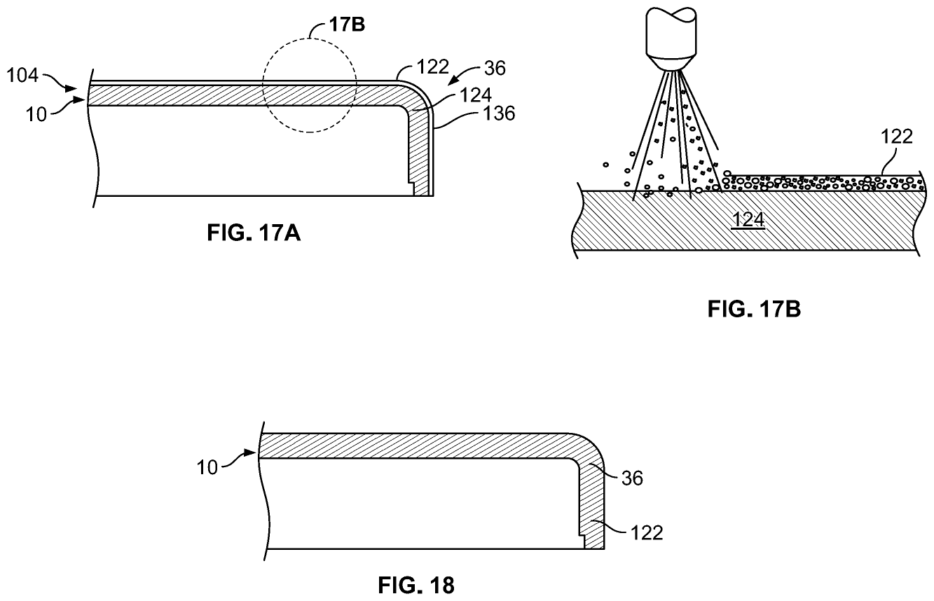

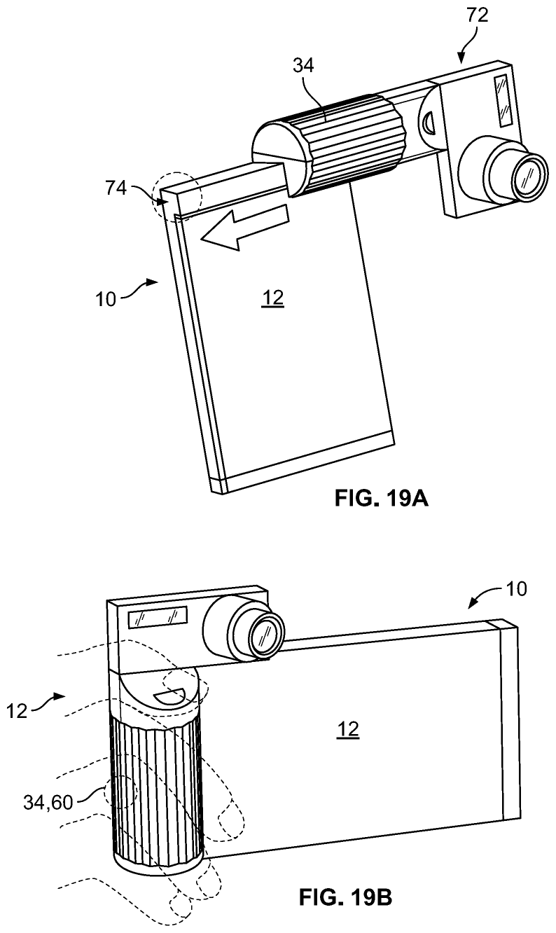

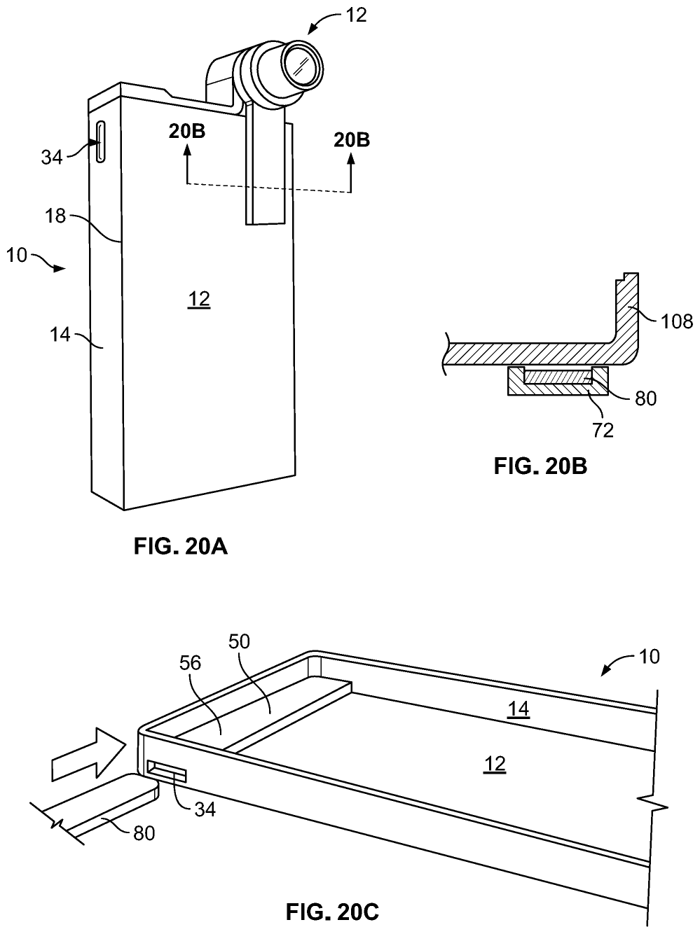

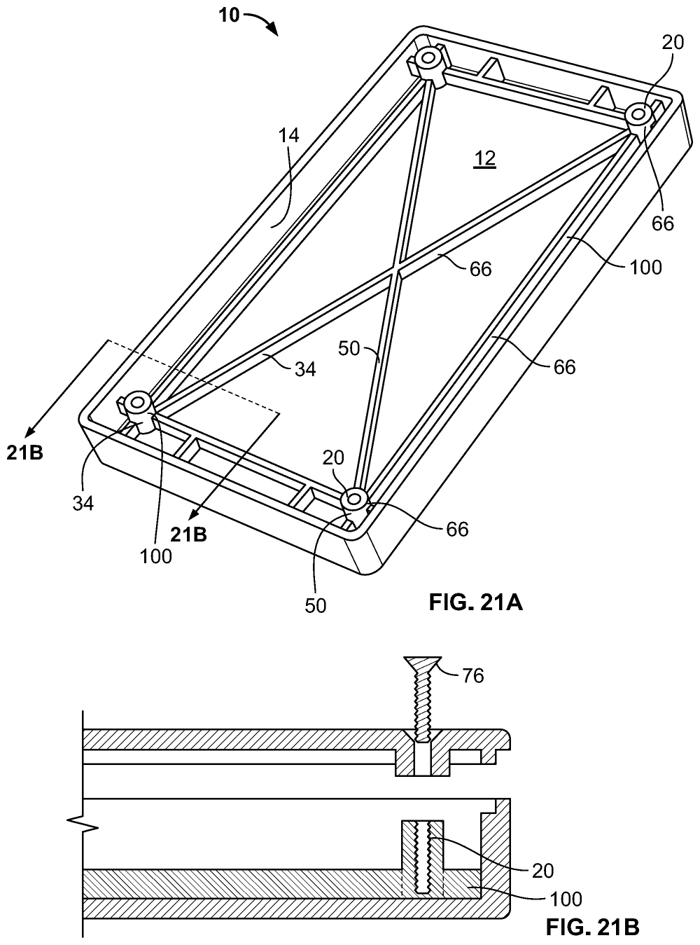

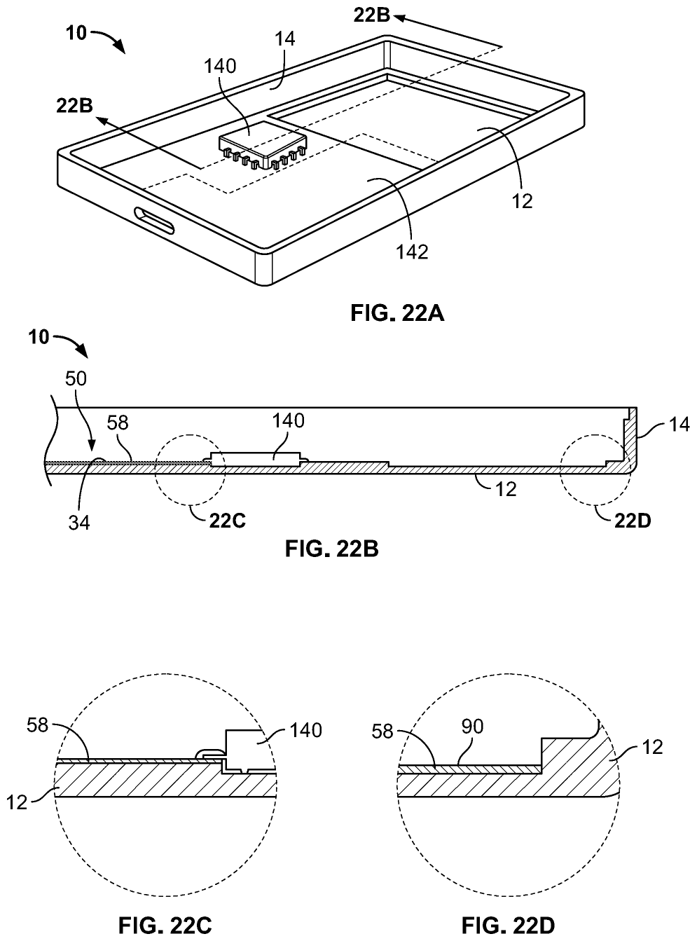

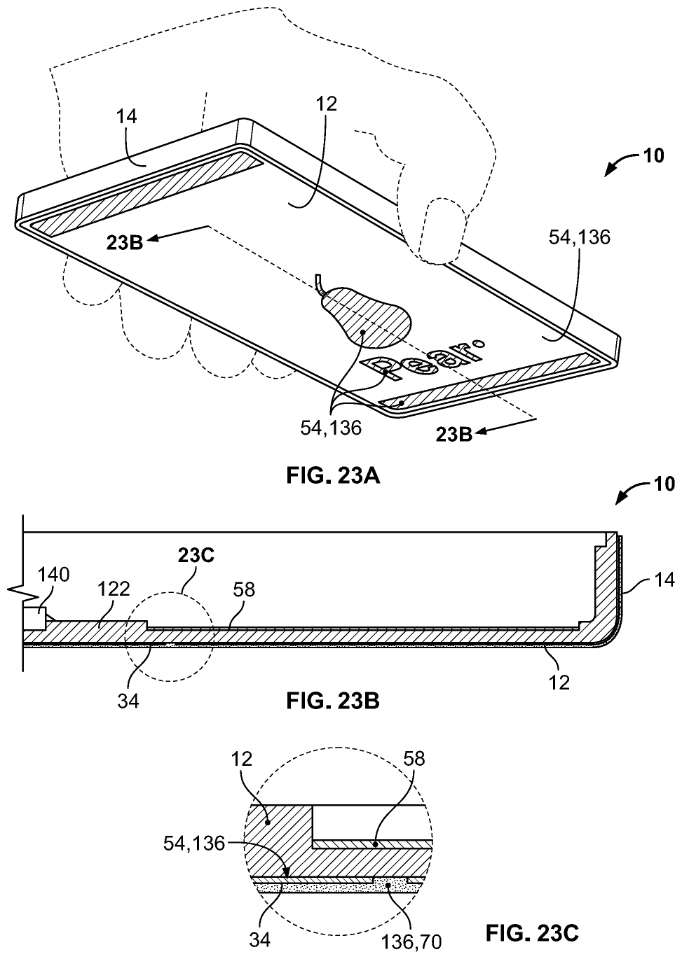

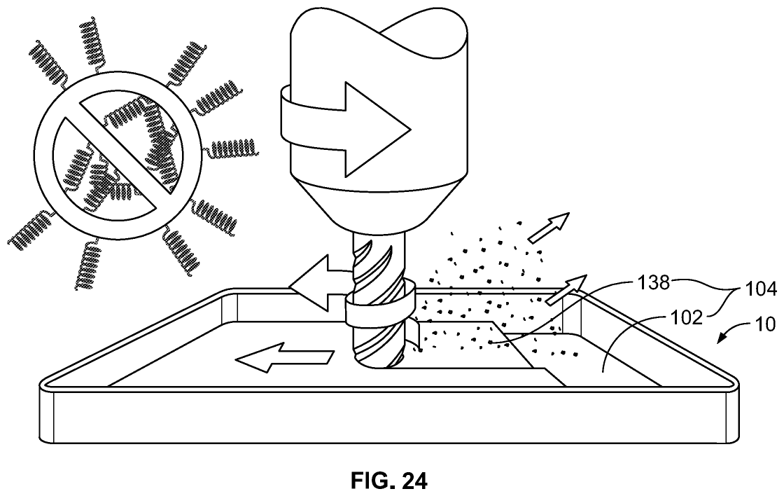

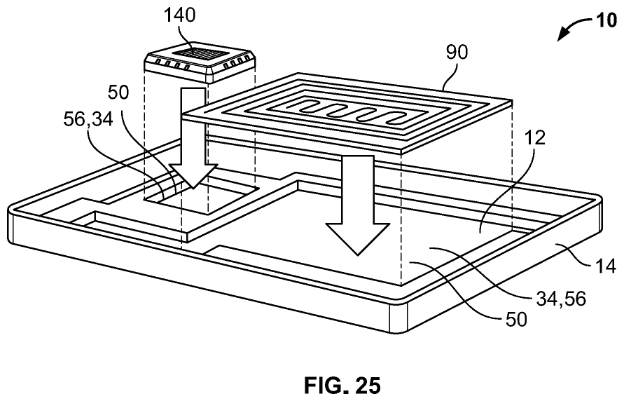

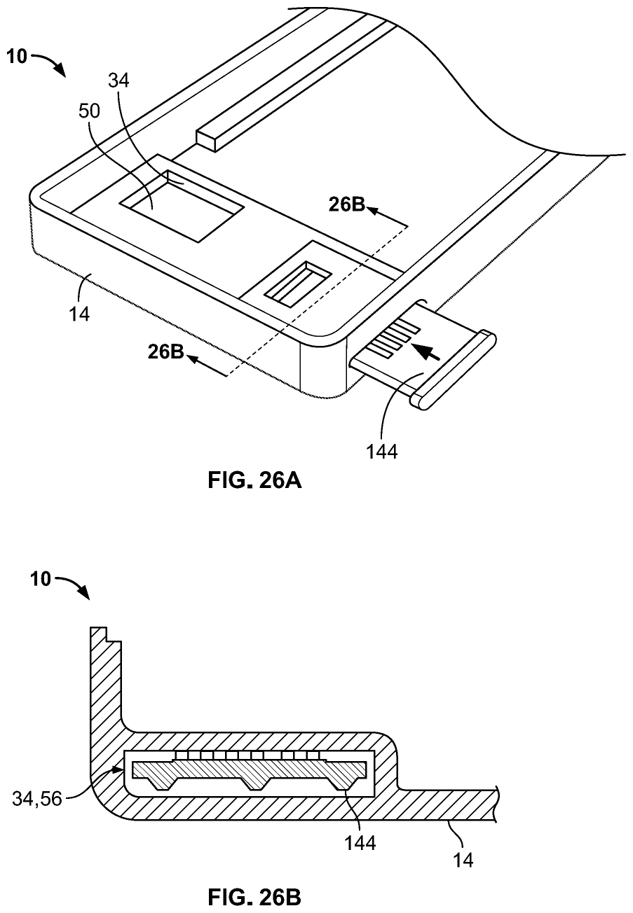

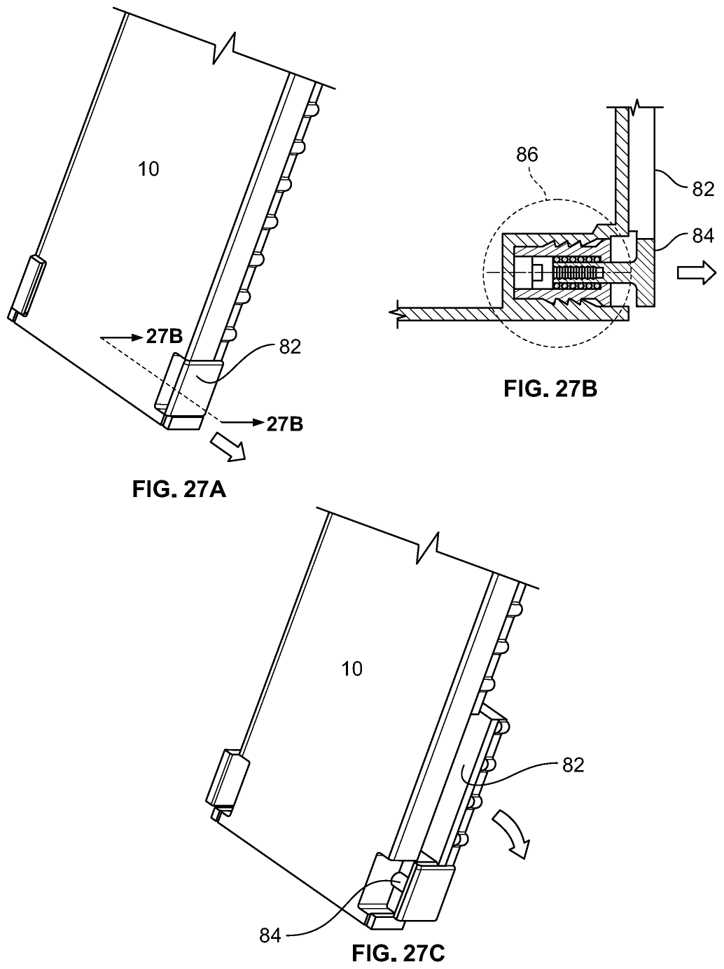

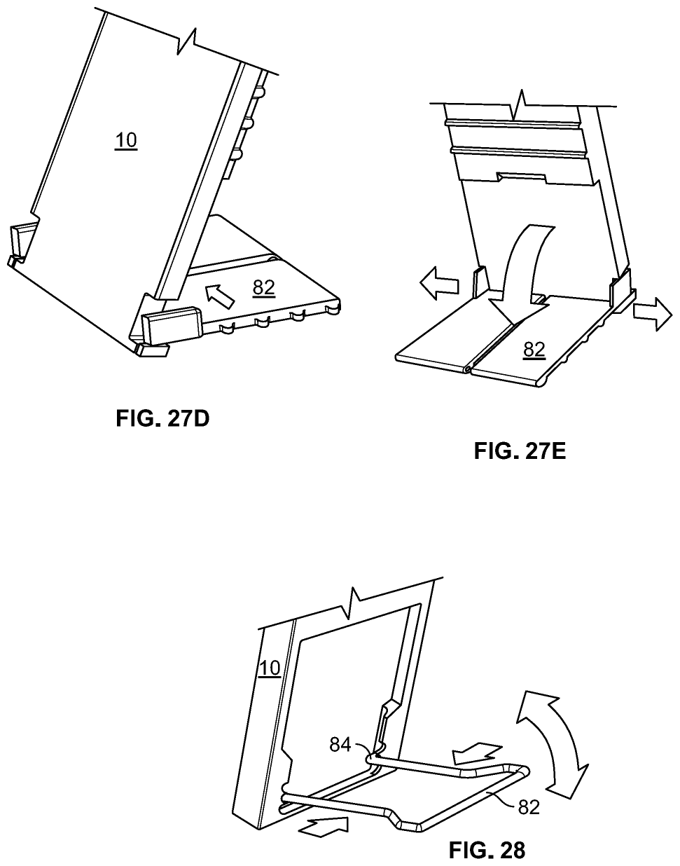

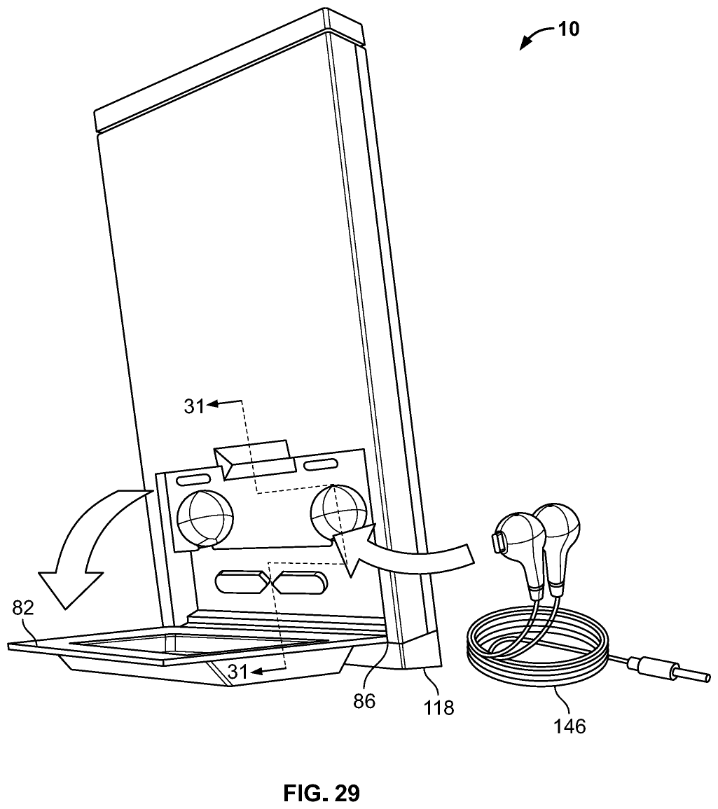

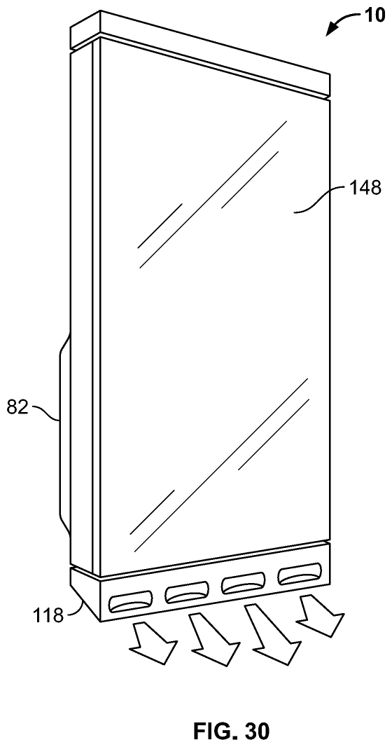

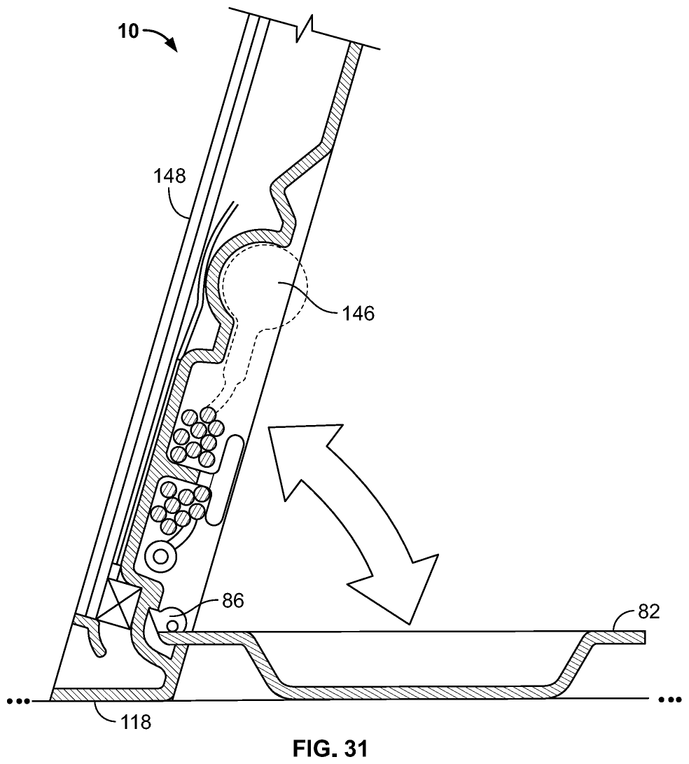

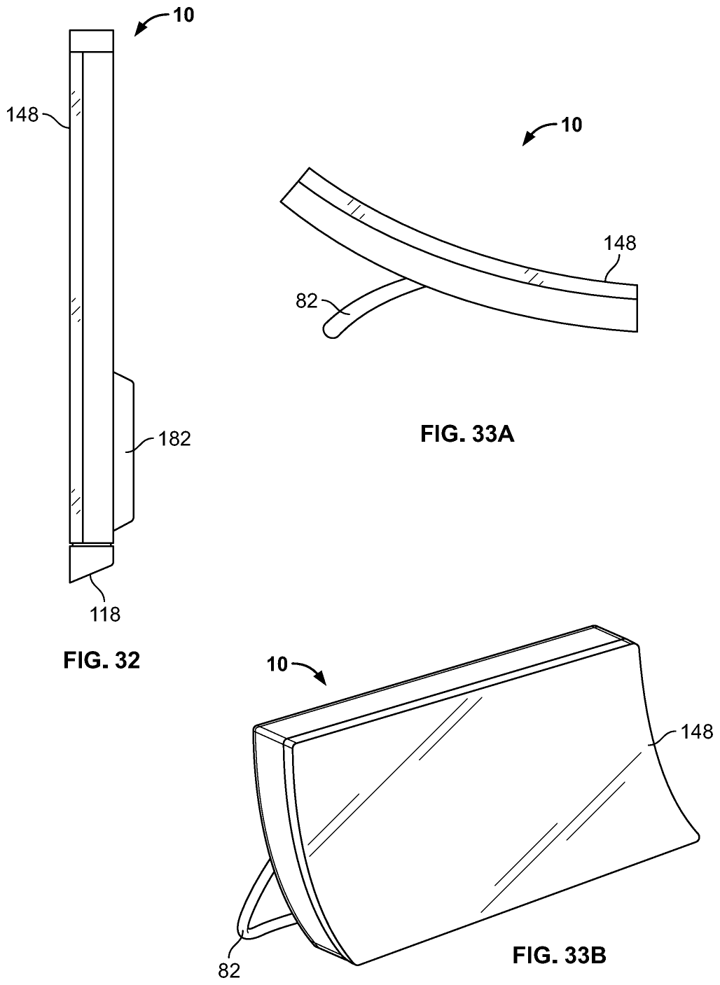

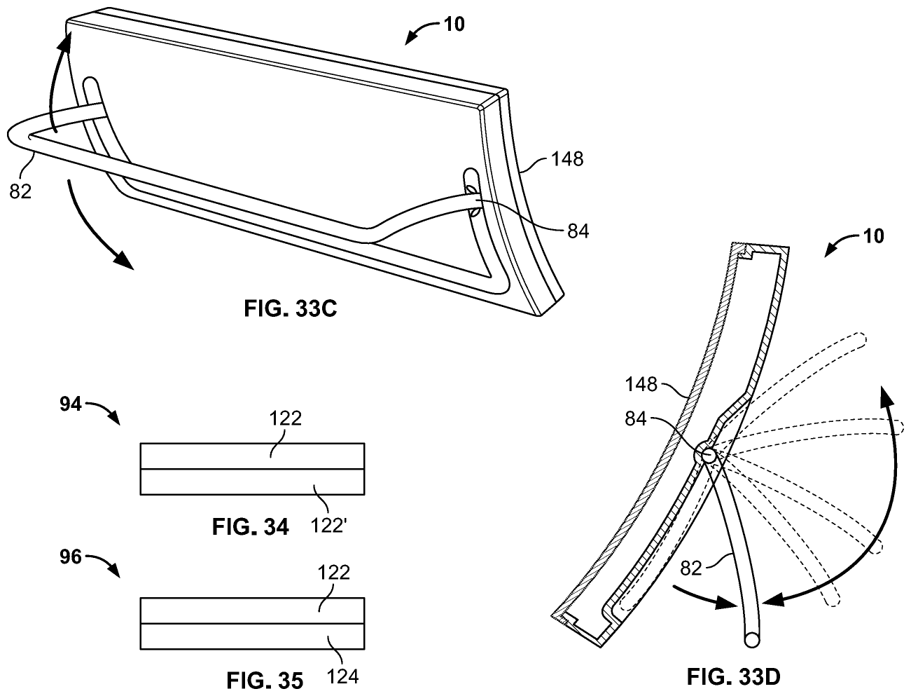

In this embodiment, both AM components for the palm rest and finger grips are additively manufactured onto the case and change the general profile of the case, as the palm portion (a) extends outwardly from the case profile, while the finger grips (b) are configured inwardly from the general profile of the phone taken from the top (e.g. a position towards the flash and lens of the phone towards the bottom of the device. Also, as shown in the outer AM components comprising finger recesses on the case, there are additional raised ridges configured in a parallel and spaced configuration to provide additional tactile gripping portions transverse the user's fingertips. In this embodiment, the outer AM components, individually and combination, provide for a tactile grip to enable secure and/or ergonomic user grip and retention of the consumer electronic device and/or case, in accordance with the instant disclosure.

FIGS. 9A-9C depict another embodiment of the instant disclosure, wherein multiple outer AM components are utilized in combination to provide an ergonomic and/or tactile grip on the consumer electronic device and/or case.

FIG. 9A depicts a case having an outer case wall configured with an outer AM component of a ribbed portion that extends along from sidewall to sidewall and across the body outer wall. The outer AM components 60 are surface projections that are tactile grips 64 and heat sinks 62. Also, this embodiment depicts another outer AM component 60 configured as a stand 118. In this embodiment, the stand 118 is configured as an extension along one of the sidewalls 14, such that the dimension and weight of the stand 118 provide a surface and center of gravity to the case 10 sufficient to enable the device to free-stand along the lower surface of the stand 118.

Additionally, in some embodiments and as shown in FIG. 9A, the stand is configured with surface projections that are tactile grip portions 64 to enable the stand to have frictional engagement with the surface that the device is retained upon.

FIG. 9B depicts the embodiment of FIG. 9A retained in user's hand, in accordance with the instant disclosure.

FIG. 9C depicts a close-up of the embodiment depicted in FIGS. 9A and 9B, showing a cut-away side view of the heat sink 62 and tactile grip portion 64 of outer AM component 60 on the outer case wall 22, in accordance with the instant disclosure.

FIGS. 10A-10B depict an embodiment of the instant disclosure, wherein the case 10 is configured with an inner AM component 50 on the inner case wall 24, in accordance with the instant disclosure.

FIG. 10A depicts a perspective view of the tailored layering to achieve the structural support, i.e. a first build material that the case is configured from and a second build material that the cross-hatched/diamond patterned structural support is configured from. In this embodiment, the cross-hatched and/or diamond patterned AM component is configured from a material that is higher mechanical strength than the material utilized for the case build.

FIG. 10B is a cut-away side view of the embodiment of FIG. 10A, which depicts that the first build material is utilized in between the diamond pattern of the second build material, such that the resulting inner body wall 24 and inner body sidewalls are correspondingly generally planar and/or flat.

FIGS. 11A-11B depicts various views of another embodiment of the case 10 having an AM component 34 on the outer case wall 22 in accordance with the instant disclosure.

FIG. 11A depicts a perspective view of an embodiment of an outer case wall having different AM build materials utilized in a pattern towards the uppermost layer/outer case wall 22 so as to provide different alloys with finished appearances (e.g. different shines and/or different anodize patterns in the case of aluminum alloy materials), in accordance with the instant disclosure. As shown in FIG. 11A, the resulting pattern is a series of spaced apart curved striations extending generally from the upper portion of the consumer electronics device (e.g. adjacent to the edge where the camera and flash are configured in the case of a cell phone) and terminating towards the generally opposing lower edge of the consumer electronics device outer body wall 30.

FIG. 11B depicts a cut-away side view of FIG. 11A taken along B-B line, showing in further detail that the case 10 is constructed form a first material and the curved striations are constructed from a second material with different finished appearance than the first material (e.g. in the case of aluminum alloys, the second material has a different anodized finish than the first material.)

FIGS. 12A-12B depict various views of an embodiment of a case 10 having different build layers (e.g. three different build layers), in accordance with the instant disclosure.

FIG. 12A depicts a perspective view of partial cut away side view of an embodiment of a consumer electronics case having an additively manufactured feature in the form of three different build layers: an inner layer constructed of a high thermal conductivity material, a middle layer constructed of a high strength material, and an outer layer constructed of a high finishability layer (e.g. anodizable, in the case of aluminum alloys). As shown in FIG. 12A, the layers completely encase the previous layer to provide a three-layered case. FIG. 12B depicts a cut-away side view of FIG. 12A, showing the cross-section of each of the three layers.

Referring to FIG. 12B, one non-limiting example of multi-layered materials configured into a case wall (e.g. integral case) include: two 1xxx series aluminum alloys positioned on the inner case wall and the outer case wall, with a 7xxx series alloy configured between.

As another example, two 5xxx series alloys are configured as the inner and outer case wall, with a titanium alloy configured between the two 5xxx series aluminum alloys.

As yet another example, two 1xxx series aluminum alloys are configured as the inner case wall and outer case wall, with a graphite material configured between the two layers.

As another example, the outer case wall is selected from a 1xxx series aluminum alloy or a 5xxx series aluminum alloy, while inner layer is configured from a graphite, a titanium alloy, or a 7xxx series alloy, and inner case wall is selected from a 1xxx series aluminum alloy and a 5xxx series aluminum alloy.

In one or more of the aforementioned embodiments and with reference to FIG. 12B, the inner layer (e.g. high strength) can be a continuous layer or a discontinuous layer (e.g. grid, mesh, or perforated material).

FIG. 13 depicts a cut-away side view of another embodiment, depicting a two-layered case wherein the inner layer is configured from a high strength material and the outer layer is configured from a material with high finishability, in accordance with the instant disclosure.

As one non-limiting example, the outer case wall of FIG. 13 is selected from a 1xxx series aluminum alloy while the inner case wall is configured from a titanium alloy (e.g. Ti—6-4).

As one non-limiting example, the outer case wall of FIG. 13 is selected from a 5xxx series aluminum alloy while the inner case wall is configured from a titanium alloy (e.g. Ti—6-4).

As one non-limiting example, the outer case wall of FIG. 13 is selected from a 1xxx series aluminum alloy while the inner case wall is configured from a 6xxx series aluminum alloy.

As one non-limiting example, the outer case wall of FIG. 13 is selected from a 1xxx series aluminum alloy while the inner case wall is configured from a 7xxx series aluminum alloy.

As one non-limiting example, the outer case wall of FIG. 13 is selected from a 1xxx series aluminum alloy while the inner case wall is configured from a 2xxx series aluminum alloy.

As one non-limiting example, the outer case wall of FIG. 13 is selected from a 1xxx series aluminum alloy while the inner case wall is configured from an Al'Li alloy.

As one non-limiting example, the outer case wall of FIG. 13 is selected from a 1xxx series aluminum alloy while the inner case wall is configured from a 5xxx series aluminum alloy.

FIG. 14 depicts a cut-away side view of another embodiment, depicting a two-layered case wherein the inner layer is configured from a high thermal conductivity material and the outer layer is configured from a material with high strength, in accordance with the instant disclosure.

As one non-limiting example, the outer case wall of FIG. 14 is selected from a 7xxx series aluminum alloy while the inner case wall is configured from a 1xxx series aluminum alloy.

As one non-limiting example, the outer case wall of FIG. 14 is selected from a 6xxx series aluminum alloy while the inner case wall is configured from a 1xxx series aluminum alloy.

FIGS. 15A-B depict yet another embodiment of a multi-material case wall that is depicted as a gradient layered configuration, in accordance with the instant disclosure.

FIG. 15A depicts a cut-away side view of an embodiment of a case, providing a multi-gradient material in the case wall, depicting three AM build materials: AM layer A 122 configured along the outer case wall 22, AM layer B 124 configured as the middle layer, and AM Layer C 126 configured along the inner case wall 24, in accordance with the instant disclosure.

As one non-limiting example, the outer case wall of FIG. 15A is selected from a 1xxx series aluminum alloy, while one or more materials referenced herein are employable as the inner case wall, provided the gradient component is chemically compatible (e.g. provides acceptable properties in the case).

FIG. 15B provide a close-up, detail view of the cut-away side view of the embodiment depicted in FIG. 15A, showing the AM layer A 122 and AM layer B 124 with a transition zone A-B 128 configured between the layers, and the AM layer B 124 to AM layer C 126 with transition layer B-C 130 configured between AM layer B 124 and Am layer C 126, in accordance with the instant disclosure.

As depicted in FIG. 15B, a multi-layered configuration provides for 100% AM layer A, then a gradient of AB with a mixing of A and B in the transition zone, which transitions to pure AM layer B, and then a gradient of B-C with a mixing of B and C materials in the transition zone, which transitions in a graded percentage to AM layer C, in accordance with the instant disclosure. Although FIGS. 15A-B depicts a three-layered gradient AM build, two layers, or more than three layers is also included in the instant disclosure.

FIGS. 16A-C depicts multiple views of a consumer electronics case, depicting a non-AM component embedded in the case, in accordance with the instant disclosure.

FIG. 16A depicts a cut-away side view of a non-AM component 110 deposited in the body of a case, positioned in between the inner case wall and the outer case wall. As shown in FIG. 16A, the case body is manufactured from the same material/feedstock and the non-AM component (configured as a mesh or screen with a plurality of vias) has AM material filling in the holes of the mesh or screen non-AM component.

FIG. 16B depicts a perspective view of the Non-AM component and suggest placement of the non-AM component via the arrow from 16B to 16C, in the case adjacent to the inner wall of the body, in accordance with the instant disclosure. Alternative shapes and dimensions of non-AM components embedded into the case, body, and/or sidewall are included in the instant disclosure.

FIG. 16C depicts additional AM layers being built successively upon the screen. FIG. 16C depicts feedstock 134 deposited onto the case and non-AM component 110 and an energy source positioned above the feedstock and a case configured as the build substrate and/or partial AM build. In this embodiment, the energy source (e.g. laser) is depicted as actively, additively manufacturing the deposited layers of feedstock 134 onto the case 10 to thereby embed the non-AM component into the sidewall, in accordance with the present disclosure.

FIGS. 17A-17B depict various views of a multi-layered AM case, in accordance with the present disclosure.

FIG. 17A depicts a cut-away side view of a case 10 having a first layer (e.g. material A, base layer) configured to be a surface of the inner case wall 24 and a second, separate layer (e.g. material B, deposited layer) positioned on the first layer and configured to be the surface of the outer case wall 22, in accordance with the present disclosure.

As one non-limiting example, the outer case wall material that is configured via aerosol deposition is a ceramic material.

FIG. 17B depicts a schematic view depicting one embodiment of manufacturing the embodiment depicted in 17A. In this embodiment, the base layer is deposed via additive manufacturing or through alternative pathways (extruding and machining, casting, and the like) and an aerosol deposition deposits the second layer (material B) directly onto the base layer (material A) to form an integral case constructed of two materials (material A and B), in accordance with the present disclosure. In some embodiments, the aerosol deposition process is utilized to deposit a layer of material selected from the group consisting of: ceramic powder, glass powder, aluminum nitride, and/or combinations thereof onto the outer case wall 22. In some embodiments, the aerosol deposition process is a cold spray process whereby high velocity gas impacts particles onto the substrate/surface such that the particles are embedded and/or impact deformed onto the surface to create a layer of aerosol deposited material. In an alternative embodiment, the outer case wall layer is deposited via a laser enhanced cold spray.

FIG. 18 is a cut-away side view of an embodiment of a case that is additively manufactured such that the case is configured to be high strength and anodizable, in accordance with the present disclosure.

FIGS. 19A-19B depict an embodiment of an add-on module, where attachment onto the consumer electronics case 10 is enabled via an AM component 34 selected from (a) a mechanical add-on module feature and (b) an internal pocket for retaining a ferritic component, in accordance with the instant disclosure. In some embodiments, the ferritic component enables magnetic attachment and/or retention of the add-on module.

As depicted by FIG. 19A, the telephoto lens/camera module is slid onto an AM component 23 on the outer case wall 22 of the device, wherein the AM component 34 is in the form of a mechanical attachment device. In some embodiments, the mechanical attachment device may be a rail and anchor with slide-on and click in attachment. Similarly, FIG. 19B depicts the embodiment of FIG. 19B once the telephoto lens/camera module is in place on the consumer electronics case, in accordance with the instant disclosure. As depicted in FIGS. 19A and 19B, the add-on module is depicted with tactile grip features and is configured with a profile/dimension to enable ease in user gripping of the lower portion of the add-on module configured to attach to the consumer electronics device.

FIGS. 20A-C depict multiple views of other embodiments of a case having an AM component configured therein, wherein internal AM component includes a ferritic material (e.g. magnetic AM material) and/or an internal AM component pocket configured to retain a ferritic component (e.g. a magnet) within the case. In these embodiments, the case is configured to attach to an add-on component (e.g. camera or lens module) and retain the device in position on the case through magnetic attachment of the magnetic portion of the case to the corresponding oppositely polarized magnetic portion on the attachment area of the add-on module.

FIG. 20A depicts a perspective view of the add-on module positioned and attached to the case at its magnetic/ferritic component.

FIG. 20B depicts a cut-away side view of the add-on module and case sidewall, depicting a localized AM material built into and integral with the case sidewall to provide magnetic attachment to the corresponding magnet in the add-on module, in accordance with the present disclosure. In some embodiments, the add-on module includes an aesthetic surface finish to the module and an inner magnet retained within.

FIG. 20C depicts a perspective side view of the case 10 being configured with a magnet 80, which is retained in an AM component pocket 56 to provide magnetism to a localized portion of the case sidewall (and corresponding magnetic attachment to an add-on module), in accordance with the present disclosure.

FIGS. 21A-21B depict various views of still another embodiment of a consumer electronics case having inner AM components in two different structural components forms: (a) ribs and (b) bosses, where the ribs and bosses are configured in a localized region from a high strength alloy (e.g. different from the outer surface of the case, which is configured of a high finishable material (e.g. anodizable material)), in accordance with the present disclosure.

FIG. 21A depicts a perspective view of the inner sidewall of the case depicting the AM components configured as structural support ribs adjacent to the perimeter of the sidewall and extending from corner to corner in a “x” configuration, while the other structural support component, bosses, are depicted as upward extensions from the inner case wall, positioned adjacent to the sidewall-to-sidewall edges, in accordance with the present disclosure.

FIG. 21B depicts a cut-away side view of FIG. 21A, also depicting the second case portion (e.g. cover) that is mechanically attached to the case via the bosses and mechanical attachment devices (e.g. screws), in accordance with the present disclosure. As shown in FIG. 21B, the ribs and bosses (e.g. inner case sidewall portions) are configured from a different material than the remainder of the case (e.g. outer case sidewall), wherein the inner AM components are configured from a high strength alloy (e.g. to impart rigidity and strength to the case as structural components).

FIGS. 22A-22D depicts several embodiments of inner AM components of the case, including AM component pockets and/or a conductive ink utilized in conjunction with: a circuit, an electrical connection of the circuit to the power source, and/or an antenna, in accordance with the present disclosure.

FIG. 22A depicts a perspective view of a case 10 which has an inner AM component configured as an AM component pockets, which are more clearly depicted in FIG. 22B. FIG. 22A also depicts a circuit, which in some embodiments, is electrically connected to the power source via an additively manufactured/deposited conductive ink. In other embodiments, the conductive ink is a non-AM component which electrically connects the circuit to the power source (e.g. battery 142). In some embodiment, the circuit is partly or completely additively manufactured.

FIG. 22B depicts a cut-away side view taken along the A-A axis in FIG. 22A, which provides more detail to the configuration of the circuit 140 which has conductive ink 58 configured as an inner AM component 50, connecting the circuit 140 to the power source 142. Also, FIG. 22B depicts an inner AM component 50 as an AM component pocket 54, where a conductive ink 58 antenna 90 is configured in the AM component pocket 50, in accordance with the present disclosure.

FIG. 22C depicts a partial close-up cut-away side view of view A in 22B, showing the body 12 having an inner AM component 50 defined as an AM component pocket 54 configured to retain a circuit 140 therein, where a conductive ink 58 is configured to extend from the circuit to a power source 142 (e.g. battery) to provide electrical connection/contact between the two components, in accordance with the present disclosure.

FIG. 22D a partial close-up cut-away side view of view B in 22B, showing the body 12 having an inner AM component 50 defined as an AM component pocket 54 configured to retain an antenna 90 configured from a conductive ink 58 (e.g. additively manufactured), where the conductive ink 58 is configured to extend from the antenna 90 to a power source 142 (e.g. battery) to provide electrical connection/contact between the two components, in accordance with the present disclosure.

FIGS. 23A-23C provide various views of an alternative embodiments of an inner AM components in combination on the case 10, including an electroluminescent ink 54 configured along an internal AM component pocket 54 of the case, in accordance with the present disclosure.

FIG. 23A depicts a perspective top view of a case 10 having an inner AM component 50 visually observable from a position external to the case 10. As shown in FIG. 23A, the AM component pocket 54 is configured as a hole extending from the outer body wall 30 to the inner body wall 32, and defining the perimeter of a logo or pattern 132 therein. On the outer case wall 22, a coating 136 (e.g. clear coating) is configured over the hole and extending at least a portion over the adjacent outer body wall 32, including extending over the body 12 and/or sidewall 14 of the case 10. Onto the clear coating 136 the hole is coated (e.g. filled) with an electroluminescent ink 54, which is electrically configured to attached/connect to the power supply 142. The electrical communication/configuration enables the power source 142 to provide illumination to the electroluminescent ink 54, thus creating a glowing logo and/or pattern 132 visually observable from the outer case wall 22 by a user/observer of the consumer electronics case, in accordance with the present disclosure.

FIG. 23B depicts a partial cut-away side view of view of FIG. 23A along view B-B, providing greater detail of the configuration of the layers of the coating 136 in relation to the conductive ink 58 within the body 12 of the case 10, in accordance with the present disclosure.

FIG. 23C depicts a close-up, partial cut-away side view of view C from FIG. 23B, depicting the configuration of various components, including the coating 136 on the outer case wall 22 covering the hole over which extends the electroluminescent ink 54. Further, FIG. 23C depicts a portion of the body 12 between the electroluminescent ink 54 and the conductive ink 58 configured adjacent to the inner body wall 30, in accordance with the present disclosure.

FIG. 24 depicts a perspective view of a case 10 composed of a machineable material, in accordance with the present disclosure. As depicted by FIG. 24, as the machining mill head is directed across the inner case wall 22 to create pockets and indentations to retain the electrical components and innards of the consumer electronics device, the machinable material is configured to produce fine particles rather than coiled machining scrap.

FIG. 25 depicts a perspective view of another embodiment of inner AM components on a case, configured as a plurality of AM component pockets 56 on the inner case wall 22 (e.g. configured for the circuit 140 and the antenna 90), in accordance with the present disclosure.

FIGS. 26A-26B depict various views of an embodiments of a consumer electronics case with inner AM components configured as AM produced case with an AM component pocket 56, in accordance with the instant disclosure.

FIG. 26A depicts a partial perspective view of an AM component pocket 56 configured in the case 12 and designed to retain the sim card 144 of the consumer electronics device, in accordance with the instant disclosure.

FIG. 26B depicts a partial cut-away side view of a close-up of view A-A from FIG. 26A, depicting a cross-sectional view of the sim card 144 retained in the AM component pocket 54 of the inner AM component 50 configured in the body 12 and sidewall 14 of the case 10, in accordance with the present disclosure.

FIGS. 27A-27E depict various views showing the operation of a stand 82 of the case with a case 10 configured for stand attachment with a stand attachment device 84 attached to the stand, in accordance with the instant disclosure.

FIGS. 27A, 27C, 27D, and 27E depict various perspective views showing the case 10 with the stand 82 in stored/retained position (27A), the stand pulled out to reveal a spring-loaded stand and pivoted down to the desired screen viewing angle (27C), the spring in the stand 82 released to drop the stand adjacent to the support surface to retain the case in a generally vertical, angled configuration via the stand 82 (27D) and the opposing perspective views from 27A, C, and D, depicting the rear of the device and illustrating the adjustable nature of the stand 82, in accordance with the present disclosure.

FIG. 27B depicts a partial cut-away side view of a close-up of A-A depicted in FIG. 27A, showing the details of the stand mechanical attachment and retention device, which is configured as a spring loaded press fit assembly, in accordance with the present disclosure.

FIG. 28 depicts an alternative embodiment to the stand 82 attached to the case, wherein the stand attachment device is configured as an additively manufactured hip-like joint configured to enclose and retain the ends of the stand 82, configured as ball joints, such that the stand is rigidly attached but free to move generally along the stand axis to provide different adjustable view angles to the user, in accordance with the instant disclosure.

FIG. 29 depicts a perspective rear view of another embodiment of a case having integrated AM components on the case, in the form of an external AM component pocket configured to retain phone accessories (e.g. charging cable, ear buds, and/or the like), including a stand 82 that is configured in the open position to enable vertical and/or angled positioning adjacent to a surface and in the closed position, to enable storage and enclosure of the external AM component pocket and consumer electronics accessories retained therein), in accordance with the present disclosure.

FIG. 30 depicts a perspective front view of another embodiment of case 10 having integrated AM components on the external portion of the case configured as speaker cavities configured for acoustically distributing audio and/or sound from the consumer electronics device, in accordance with the present disclosure.

FIG. 31 depicts a cut-away side view of another embodiment of a case having integrated AM components on the inner case wall 22 and a stand 82 configured when opened to retain the device in an upright position (e.g. vertical or angled) and when closed to retain the phone accessories and integral AM component pockets (e.g. earbud indents) and retention features (e.g. integral earbud cord anchor/cord wrap), in accordance with the present disclosure.

FIG. 32 depicts a plan side view of the embodiment depicted in FIG. 31, illustrating the profile of the case 10 and device when the stand 82 is in a closed configuration, in accordance with the present disclosure.

FIGS. 33A-D depict various views of a consumer electronics device having a curved and/or flexible screen and corresponding case, in accordance with the present disclosure.

FIG. 33A depicts a plan side view showing the stand 82 in an open position, in accordance with the present disclosure.

FIG. 33B depicts a perspective front view illustrating the curved OLED screen and the corresponding case configuration to retain the screen, with the stand 82 in an open position, in accordance with the present disclosure.

FIG. 33C depicts a rear perspective view, and generally opposing arrows depict the adjustable nature of the stand and its ability to be positioned up or down and adjust the angle by which the curved screen is displayed to a user, in accordance with the present disclosure.

FIG. 33D depicts a plan side view of the case with stand 82, and depicts with arrow and dashed lines the various positions that the stand 82 is able to sit in, thereby adjusting the angle of view that the user views the device screen, in accordance with the present disclosure.

FIG. 34 depicts a schematic view of a multi-characteristic AM case 94, which includes the same build materials in a different build parameter (122 and 122′) to create a multi-characteristic case wall 10, in accordance with the present disclosure.

FIG. 35 depicts a schematic view of a multi-characteristic AM case 94, which includes the different build materials (122, 124) in an AM build (same or different build parameters) to create a multi-characteristic case wall 10, in accordance with the present disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation

### DETAILED DESCRIPTION

Reference will now be made in detail to the accompanying drawings, which at least assist in illustrating various pertinent embodiments of the present invention.

In one embodiment, a consumer electronics case having an additively manufactured feature thereon is described herein.

In one embodiment, the case is includes a body and at least one sidewall attached to and extending perimetrically around the body to define an inner case wall and an outer case wall. In some embodiments, the inner case wall defines an inner cavity and area to house device electronic components. In some embodiments, the outer case wall defines the surface that the user interacts with.

In some embodiments, extending perimetrically around comprises partial enclosure of the body.

In some embodiments, extending perimetrically around comprises complete encirclement of the body.

In one embodiment, a consumer electronics case having an additively manufactured feature (i.e. AM component) on the inner wall of the case, configured as an inner AM component.

In one embodiment, the inner AM component is selected from the group consisting of: a structural support; an electroluminescent ink; a conductive ink; a component pocket; and combinations thereof.

In some embodiments, the conductive ink is selected from the group consisting of Ag, Cu, Ni, Al, Pt, Au, and combinations thereof.

In some embodiments, the conductive inks are selected from inorganic or organic binders or reactive agents.

In some embodiments, the conductive inks are configured onto the case via inkjet printing, a droplet-based process, additively manufacturing via an Optomec AM machine, direct-write assembly, or a combination thereof. In some embodiments, the direct-write assembly process involves the extrusion of ink filaments either in- or out-of-plane.

In some embodiments, the electroluminescent ink is AM deposited via a binder jet AM machine.

In one embodiment, a consumer electronics case has an additively manufactured component on the outer sidewall of the case configured as an outer AM component.

In one embodiment, the outer AM component is selected from the group consisting of: a structural support; a heat sink; a tactile grip portion; an aesthetic component; a stand; an attachment device; an audio outlet portion; device accessories attachment/stow area; and combinations thereof. In some embodiments, the attachment device may be used for a device stand, a camera module, magnetically attached accessories, or the like. In some embodiments, an audio outlet portion includes a speaker cavity portion to accommodate speakers or to enhance acoustic fidelity. In some embodiments, the device accessories attachment/stow area is configured for headphones, charging cable storage, or the like.

In one embodiment, the case is additively manufactured and configured to accept a non-AM component therein. In some embodiments, the non-AM component is selected from the group consisting of: an electroluminescent ink; a conductive ink; a device configured to be retained in an AM component pocket; and combinations thereof. In some embodiments, an electroluminescent ink is a glowing logo or device/aesthetic configuration. In some embodiments, a conductive ink is a printable circuit, or antenna. In some embodiments, a device configured to be retained in an AM component pocket is a housing battery, a circuit, a magnet, or the like.

In some embodiments, the case is configured for a consumer electronics device.

In some embodiments, the case is configured from a metallic material.

In some embodiments, the AM component is configured from a metallic AM material.

In some embodiments, the metallic AM material is selected from the group consisting of: a finishable material; a high strength material; a thermally conductive material; machineable material; and combinations thereof.

In some embodiments, a finishable material comprises: an aesthetic visual observation surface, a scratch resistant surface, a corrosion resistant surface, a surface durable to UV exposure; and combinations thereof.

In some embodiments, the finishable material comprises an anodizable material configured to provide a surface ranging from highly polished to matte finish.

In some embodiments, the anodizable material extends along at least a portion of the inner case wall, such that via the anodizable material the case is configured with an electrically insulating substrate, an electrically insulating surface, or combinations thereof to configure additional electrical components thereon. In some embodiments, the additional electrical components can include but are not limited to: print conductive ink, connect electrical circuitry, configure antennae, or combinations thereof.

In some embodiments, the finishable material comprises: a high purity aluminum alloy (e.g. 1xxx type alloys); a matte finish alloy (e.g. 7xxx series aluminum alloys (e.g. 7075), 6xxx series aluminum alloys (e.g. 6063), 5xxx series aluminum alloys (e.g. 5052, 5657)), and combinations thereof.

In some embodiments, the machineable material comprises a 2xxx series aluminum alloy, a 3xxx series aluminum alloy, a 5xxx series aluminum alloys, a 6xxx series aluminum alloy, a 7xxx aluminum alloy, and combinations thereof.

In some embodiments, the case is configured from two or more of the aforementioned AM materials.

In some embodiments: the high strength material comprises: titanium alloys (e.g. Ti—6Al—4V), 7xxx series aluminum alloys (e.g. 7075, 7085), Al—Li alloys (e.g. 2099, 2055, 2060); dispersion strengthened alloys (e.g. Al—Ni—Mn alloys, Al—Si—Cu alloys; Al—Cu—Ni alloys; and Al—Fe alloys Al—Fe—X alloys, where X is a transition metal or rare earth element); aluminum based metal matrix composites (e.g. 2xxx series aluminum alloys, 6xxx series aluminum alloys, or 7xxx series aluminum alloys, and metal materials having ceramic particles configured (e.g. dispersed) therein, wherein non-limiting examples of ceramics include: TiB2, TiC, SiC; Al2O3, BN, BC, TiC, WC, and combinations thereof)), and combinations thereof.

In some embodiments, the AM feedstock is selected from the group consisting of: an aluminum alloy (e.g. 2xxx series aluminum alloys, 5xxx series aluminum alloys, 6xxx aluminum alloys, 7xxx aluminum alloys, Al—Li aluminum alloys, a dispersion strengthened alloys (e.g. Al—Ni—Mn alloys, Al—Si—Cu alloys; Al—Cu—Ni alloys; Al—Fe alloys; Al—Fe—X alloys, where X is a transition metal or rare earth element, and combinations thereof); a magnesium alloy; titanium alloy; and combinations thereof.

In some embodiments, at least a portion of the case is additively manufactured. In some embodiments, portions of the case that can be additively manufactured include the body, the sidewalls, and combinations thereof.

In some embodiments, the case is non-additively manufactured and has at least one AM component configured thereon (e.g. an inner AM component, an outer AM component, and combinations thereof). In some embodiments, suitable non-additive manufacturing processes include but are not limited to: extruding, rolling, casting, drawing and ironing, machining, unibody design, forging, molding, and combinations thereof.

In some embodiments, the AM component is configured from a plurality of AM feedstocks configured in distinct AM layers (e.g. configured to extend along or over one another) or in distinct AM regions (e.g. configured in proximity or adjacent to one another).

In some embodiments, the AM component is configured from a plurality of AM layers or a plurality of AM regions configured as a gradient from a first layer to a second layer.

In some embodiments, the AM component is a localized portion. In some embodiments, the localized portion includes but is not limited to: a ferritic portion, a machineable portion, and attachment areas.

In some embodiments, the AM component or AM case is configured with a non-AM component. In some embodiments, the AM component includes but is not limited to: embedded screen, clear coating on outer case wall, conductive ink; electroluminescent ink, and combinations thereof. In some embodiments, the AM case is additively manufactured with a non-AM component.

In some embodiments, the non-AM component is an antennae. In some embodiments, the non-AM component includes but is not limited to an embedded screen, a conductive ink, or combinations thereof.

In some embodiments, the consumer electronics devices include: portable and/or handheld consumer electronics devices. In some embodiments, the consumer electronics case is configured to hold a portable and/or hand-held consumer electronics device.

In some embodiments, the case is additively manufactured with a powder based deposition.

In some embodiments, the AM machine is selected from the group consisting of: a directed metal deposition (e.g. Optomec® machine) and a laser powder bed machine (e.g. eos® machine).

In one embodiment, a consumer electronics case configured from a metallic material, the consumer electronics case having: a body; at least one sidewall attached to and extending perimetrically around the body to define an inner case wall and an outer case wall, wherein the inner case wall is configured to define an inner cavity to house a plurality of electronic components; and an additively manufactured feature configured on the inner case wall from the metallic material; wherein the additively manufactured feature is a plurality of AM builds along at least a portion of a length of the inner case wall, and wherein the plurality of AM builds are configured to provide structural support to at least one of the body and sidewall.

In some embodiments, the AM builds configured as the structural support are positioned proximate to the body-to-sidewall edge of the case.

In some embodiments, the AM builds configured as the structural support are positioned proximate to the sidewall-to-sidewall edge of the case.

In some embodiments, the AM builds configured as the structural support are positioned to extend along the entire inner surface of the case.

In some embodiments, the AM builds configured as the structural support are positioned to extend along the entire inner surface of the body.

In some embodiments, the AM builds are configured as: a plurality of raised ridges, with an interspaced configuration.

In some embodiments, the AM builds are configured as: a grid pattern comprising a plurality of AM builds that are intersecting raised lines configured orthogonally to one another.

In some embodiments, the builds are configured to enable attachment of a flexible OLED to the case.

In one embodiment, a consumer electronics case configured from a metallic material, the consumer electronics case having: a body; at least one sidewall attached to and extending perimetrically around the body to define an inner case wall and an outer case wall, wherein the inner case wall is configured to define an inner cavity to house a plurality of electronic components; a flexible OLED display configured to extend across the inner cavity and communicate with the plurality of electronic components; and an additively manufactured feature configured on the inner case wall from the metallic material; wherein the additively manufactured feature is a plurality of AM builds along the case (e.g. outer edge of the sidewall) to provide mechanical attachment of the flexible OLED to the case while permitting the flexible OLED display and corresponding inner case wall to flex and/or adjust within threshold movement parameters (i.e. a predefined range of movement that the device can move in based on the range of motion of the device/case and the overall rigidity and flexibility of the device/case). In some embodiments, the flexible OLED display is configured to extend across the entire inner cavity. In some embodiments, the flexible OLED display is configured to extend across a portion of the inner cavity.

In one embodiment, a consumer electronics case configured from a metallic material, the consumer electronics case having: a body; at least one sidewall attached to and extending perimetrically around the body to define an inner case wall and an outer case wall, wherein the inner case wall is configured to define an inner cavity to house a plurality of electronic components; at least one hole defined in the body and extending from the inner case wall to the outer case wall; a coating configured on the outer case wall and extending across the hole defined in the body; and a first additively manufactured feature configured on the inner case wall from the metallic material; wherein the first additively manufactured feature is an electroluminescent ink that is additively deposited in the hole along an inner surface of the coating; and a second additively manufactured feature on the inner case wall configured as a conductive ink configured between the electroluminescent ink and the power source to enable electrical communication and between the power source and the electroluminescent ink to illuminate the electroluminescent ink. In some embodiments, the power source is a battery; AC power; DC power; and combinations thereof.

In some embodiments, an electrical insulator is positioned between the inner case wall and the conductive ink.

In some embodiments, the electrical insulator is selected from the group consisting of: ceramics, glass, polymer, and combinations thereof.

In some embodiments, the electrical insulator is additively manufactured in place on the case.

In some embodiments, the electrical insulator is deposited via conventional routes including but not limited to: painting, spraying, coating, and combinations thereof.

In some embodiments, the electroluminescent ink is selected from the group consisting of: an irradiated polymer coating; electrochromic polymers, electronic ink, electrophoretic displays, and combinations thereof.

In some embodiments, the coating is a clear coating.

In some embodiments, the coating is a translucent coating (e.g. tinted), configured to transmit light.

In some embodiments, the coating is an opaque coating.

In some embodiments, the clear coating is selected from the group consisting of: acrylics, epoxys, polyesters, polyurethanes, fluoropolymers, silozanes, siloxanes, and combinations thereof.

In some embodiments, the translucent coating is selected from the group consisting of: acrylics, epoxys, polyesters, polyurethanes, fluoropolymers, silozanes, siloxanes, and combinations thereof, with additives to modify light transmission (e.g. configured to make the coating translucent).

In some embodiments, the opaque coating is selected from the group consisting of: acrylics, epoxys, polyesters, polyurethanes, fluoropolymers, silozanes, siloxanes, and combinations thereof, with additives to modify light transmission (and make the coating opaque).

In one embodiment, a consumer electronics case configured from a metallic material, the consumer electronics case having: a body; at least one sidewall attached to and extending perimetrically around the body to define an inner case wall and an outer case wall, wherein the inner case wall is configured to define an inner cavity to house a plurality of electronic components; at least one hole defined in the body and extending from the inner case wall to the outer case wall; a coating configured on the outer case wall and extending across the hole defined in the body; and an electroluminescent ink positioned on an inner sidewall of the coating and extending across the surface of the coating to fill in the hole; and an additively manufactured feature on the inner case wall, wherein the additively manufactured feature is a conductive ink configured between the electroluminescent ink and the power source (e.g. battery) to enable electrical communication between the power source and the electroluminescent ink to illuminate the electroluminescent ink.

In one embodiment, a consumer electronics case configured from a metallic material, the consumer electronics case having: a body; at least one sidewall attached to and extending perimetrically around the body to define an inner case wall and an outer case wall, wherein the inner case wall is configured to define an inner cavity to house a plurality of electronic components; an electrical insulator material positioned along at least a portion of the inner side wall of the body and extending across at least a portion of the inner surface of the body to fill in the hole; and an additively manufactured feature comprising a conductive ink, wherein a conductive ink is configured to provide an AM antenna, wherein the AM antenna is positioned onto the electrical insulator material and configured to be in electrical communication with the power source (e.g. battery).

In one embodiment, a consumer electronics case configured from a metallic material, the consumer electronics case having: a body and at least one sidewall attached to and extending perimetrically around the body to define an inner case wall and an outer case wall, wherein the inner case wall is configured to define an inner cavity to house a plurality of electronic components; an electrical insulator material positioned along at least a portion of the inner side wall of the body and extending across at least a portion of the inner surface of the body to fill in the hole; and an additively manufactured feature comprising a conductive ink, wherein a conductive ink is configured to provide a AM printed circuit, wherein the AM printed circuit is positioned onto the electrical insulator material and configured to be in electrical communication with the power source (e.g. battery).

In one embodiment, a consumer electronics case configured from a metallic material, the consumer electronics case having: a body; at least one sidewall attached to and extending perimetrically around the body to define an inner case wall and an outer case wall, wherein the inner case wall is configured to define an inner cavity to house a plurality of electronic components and an outer case wall; and an additively manufactured feature comprising component pocket defined by an AM build to define the component pocket, wherein the component pocket is configured to accept a device selected from the group consisting of: a magnet; a power source, a circuit board, and combinations thereof. In some embodiments, the power source is a battery.

In one embodiment, a consumer electronics case configured from a metallic material, the consumer electronics case having: a body; at least one sidewall attached to and extending perimetrically around the body to define an inner case wall and an outer case wall, wherein the inner case wall is configured to define an inner cavity to house a plurality of electronic components and an outer case wall; and an additively manufactured feature configured on the outer case wall from the metallic material; wherein the additively manufactured feature is a plurality of AM builds along at least a portion of the length of the outer sidewall, wherein the plurality of AM builds are configured to provide at least one of: a structural support to the case; a structural support to the body; a structural support to the sidewall; a structural support to the sidewall-to-sidewall edge; a structural support to the sidewall-to-body edge; a stand (e.g. to position the case in an angled vertical or horizontal configuration along a flat surface); a tactile grip configured for user interface; an aesthetic pattern; a heat sink; and combinations thereof.

In one embodiment, a consumer electronics case configured from a metallic material, the consumer electronics case having: a body; at least one sidewall attached to and extending perimetrically around the body to define an inner case wall and an outer case wall, wherein the inner case wall is configured to define an inner cavity to house a plurality of electronic components and an outer case wall; and an additively manufactured feature configured on the outer case wall from the metallic material; wherein the additively manufactured feature is a plurality of AM builds along at least a portion of the length of the outer sidewall, wherein the plurality of AM builds are configured to provide at least one of: a structural support to the case, the body, the sidewall, and combinations thereof; a structural support to the edges of the case (e.g. sidewall-to-sidewall edge or sidewall-to-body edge); a tactile grip configured for user interface; a stand (e.g. configured to enable positioning of the case in an angled vertical or horizontal configuration along a flat surface);an aesthetic pattern; a heat sink configured to dissipate heat generated by the device; and combinations thereof.

In some embodiments, the AM builds are configured proximate to the body-to-sidewall edge of the outer sidewall of the case.

In some embodiments, the AM builds are configured proximate to the sidewall-to-sidewall edge of the outer sidewall of the case.

In some embodiments, the AM builds are configured to extend along the entire outer surface of the case.

In some embodiments, the AM builds are configured to extend along the entire outer surface of the body.

In some embodiments, the AM builds are configured as: a plurality of raised ridges, with an interspaced configuration.

In some embodiments, the AM builds are configured as: a grid pattern comprising a plurality of AM builds that are intersecting raised lines configured acute, orthogonal, or obtuse to one another.

In some embodiments, the AM builds are configured as: a grid pattern comprising a plurality of AM builds that are intersecting raised lines configured orthogonally to one another.

In some embodiments, the AM builds are configured as: a plurality of raised ridges, with an interspaced configuration in a sunburst pattern.

In some embodiments, the AM builds are configured as polygonal shapes, geometric shapes, asymmetrical patterns, symmetrical patterns, and combinations thereof.

In some embodiments, the AM builds are configured as: a plurality of circles, with an interspaced configuration.

In some embodiments, the AM builds are configured as: a plurality of circles, with an interspaced, overlapping, or combinations configuration.

In some embodiments, the AM builds are configured as: a plurality of circles, with an interspaced concentric configuration.

In some embodiments, the AM builds are configured as: a plurality of raised ridges with interspaced positioning, wherein the ridges generally correspond to a user's biometric data (e.g. handprint, grip, finger positioning, etc.)

In some embodiments, the AM builds are configured as: an AM build on the case configured to extend in an outward direction from the case profile and generally conforming to the user's biometric data.

In some embodiments, the device is configured as: an additively manufactured case having at least one grip portion configured on the case and extending generally to extend in an outward direction from the case profile and generally conforming to the user's biometric data.

In some embodiments, the stand is configured to extend from the sidewall at an angle, such that the angled surface of the stand is configured to sit on a generally flat surface and retain the case in a corresponding angled vertical position.

In some embodiments, the stand is configured to extend from the sidewall at an angle, such that the angled surface of the stand is configured to sit on a generally flat surface and retain the case in a corresponding angled vertical position, further wherein portion of the stand that interfaces with the generally flat surface is configured with frictional members to promote static friction between the stand and the generally flat surface.

In some embodiments, the stand is configured to extend from the sidewall at a stepped angle configuration, such that the plurality of angled surfaces enables the stand to sit on a generally flat surface at a corresponding angles to the plurality of angles on the stand, such that the case is retained in a corresponding plurality of angled vertical position.

In some embodiments, the stand is configured as at least one integral foot (e.g. or plurality of integral feet) on the case, such that via the stand (with integral foot), the device is configured to stand up to allow hands free viewing and/or use of device components (e.g. camera).

In one embodiment, a consumer electronics case configured from a metallic material, the consumer electronics case having: a body; at least one sidewall attached to and extending perimetrically around the body to define an inner case wall and an outer case wall, wherein the inner case wall is configured to define an inner cavity to house a plurality of electronic components; and an additively manufactured feature configured on the outer case wall from the metallic material; wherein the additively manufactured feature is an attachment device configured to accept a device stand, a camera module, ear bud attachment device, and combinations thereof.

In one embodiment, a consumer electronics case configured from a metallic material, the consumer electronics case having: a body; at least one sidewall attached to and extending perimetrically around the body to define an inner case wall and an outer case wall, wherein the inner case wall is configured to define an inner cavity to house a plurality of electronic components and an outer case wall; and an additively manufactured feature configured on the outer case wall from the metallic material; wherein the additively manufactured feature is an audio outlet component configured to accommodate at least one speaker.

In one embodiment, a consumer electronics case is configured from a metallic material, the consumer electronics case having: a body; at least one sidewall attached to and extending perimetrically around the body to define an inner case wall and an outer case wall, wherein the inner case wall is configured to define an inner cavity to house a plurality of electronic components and an outer case wall; and an additively manufactured feature configured on the outer case wall from the metallic material; wherein the additively manufactured feature is an integrated receptacle configured to accept a biological sample (e.g. blood, urine, saliva, and the like), wherein the receptacle is equipped with a sensor for analyzing the sample. In some embodiments, the sensor is configured to communicate with the consumer electronics device on board computer or wireless capabilities to provide a result).

In some embodiments, the case is configured with a door to enclose the inner cavity (e.g. protect the sensor and/or enclose the sample during testing/evaluation).

In one embodiment, a consumer electronics case configured from a metallic material,

the consumer electronics case having a plurality of layers or regions (localized portions) selected from the group consisting of: an anodizable material; a high strength material; a thermally conductive material; machineable material; and combinations thereof; wherein the case is configured as a body and at least one sidewall attached to and extending perimetrically around the body to define an inner case wall and an outer case wall, wherein the inner case wall is configured to define an inner cavity to house a plurality of electronic components.

In some embodiments, a method is provided, comprising: providing a consumer electronics case having a body and at least one sidewall attached to and extending perimetrically around the body to define an inner case wall and an outer case wall, wherein the inner case wall is configured to define an inner cavity to house a plurality of electronic components; additively manufacturing an AM component onto the outer case wall, the outer AM component selected from the group consisting of: one or more of the aforementioned materials.

In some embodiments, a method is provided, comprising: providing a consumer electronics case having a body and at least one sidewall attached to and extending perimetrically around the body to define an inner case wall and an outer case wall, wherein the inner case wall is configured to define an inner cavity to house a plurality of electronic components; additively manufacturing an AM component onto the inner case wall, the outer AM component selected from the group consisting of: one or more of the aforementioned materials.

In some embodiments, a method is provided, comprising: selecting features to incorporate onto a consumer electronics device; additively manufacturing a metallic am feedstock onto a metallic consumer electronics case to define at least one AM component on the metallic consumer electronics case, wherein the at least one AM component is an at least one outer AM component or an at least one inner AM component.

In some embodiments, the outer AM components configured as geometric shapes, polymeric shapes, and/or patterns are configured as the same size and equidistant/uniform spacing.

In some embodiments, the outer AM components configured as geometric shapes, polymeric shapes, and/or patterns are configured as the same size and non-uniform spacing.

In some embodiments, the outer AM components configured as geometric shapes, polymeric shapes, and/or patterns are configured as different size and equidistant/uniform spacing.

In some embodiments, the outer AM components configured as geometric shapes, polymeric shapes, and/or patterns are configured as the different sizes and non-uniform spacing.

In some embodiments, the inner AM components configured as geometric shapes, polymeric shapes, and/or patterns are configured as the same size and equidistant/uniform spacing.

In some embodiments, the inner AM components configured as geometric shapes, polymeric shapes, and/or patterns are configured as the same size and non-uniform spacing.

In some embodiments, the inner AM components configured as geometric shapes, polymeric shapes, and/or patterns are configured as different size and equidistant/uniform spacing.

In some embodiments, the inner AM components configured as geometric shapes, polymeric shapes, and/or patterns are configured as the different sizes and non-uniform spacing.

As used herein, “additive manufacturing” means: process of joining materials to make objects from 3D model data, usually layer upon layer, as opposed to subtractive manufacturing methodologies.

As used herein, “additive systems” means machines and related instrumentation used for additive manufacturing.

As used herein, “direct metal laser sintering” means a powder bed fusion process used to make metal parts directly from metal powder without intermediate “green” or ‘brown’ parts.

As used herein, “directed energy deposition” means an additive manufacturing process in which focused thermal energy is used to fuse materials by melting as they are being deposited.

As used herein, “laser sintering” means a powder bed function process used to produce objects from powdered materials using one or more laser to selectively fuse or melt the particles at the surface, layer by layer, in an enclosed chamber.

As used herein, “powder bed fusion” means an additive manufacturing process in which thermal energy selectively fuses regions of a powder bed.

In some embodiments, the case and corresponding features are built through additive manufacturing. In some embodiments, the case is constructed from sheet (e.g. drawn and ironed), slug (e.g. impact extruded), extruded and machined, cast, or forged, with one or more additive manufacturing features added/configured the case, body, and/or sidewall preform to provide one or more embodiments as detailed in the present disclosure.

In some embodiments, additive manufacturing enables complex shapes to be configured onto a consumer electronics device, including the creation of a stand to enable the device to be positioned generally upright position.

In some embodiments, the case is configured with a unique hand to optimize the ergonomic grip of a user for enabling the appropriate phone and/or manipulation as a smart device.

In some embodiments, the use of non-silicon containing aluminum powder compositions are configured to enable a high degree of anodized cosmetics while promoting equal to greater strength relative to convention aluminum sheet or extruded material.

In some embodiments, the case is tailored with localized ribs, dots, or other features configured to impart structural support, strength, and/or rigidity to the case and/or enable grip of the device.

In some embodiments, the case is tailored with mechanical attachment locations configured with high durability and/or strength materials, such that durability and/or strength is imparted on internal female threads of the corresponding mechanical attachment site on the case. In some embodiments, the localized material is easier to machine (e.g. creates small chips or powder rather than shreds of coiled material when machined).

In some embodiments, conductive ink is additively manufactured onto an insulated substrate to create circuits, antennae, or electrical connections between the various device components/electrical innards.

In some embodiments, an additively printed case is configured with magnetic components to enable hands free use and/or interconnectivity with another device or module.

While various embodiments of the present invention have been described in detail, it is apparent that modifications and adaptations of those embodiments will occur to those skilled in the art. However, it is to be expressly understood that such modifications and adaptations are within the spirit and scope of the present invention.

### REFERENCE NUMBERS

### Case 10

### Body 12

### Sidewall 14

Edge between sidewall portions 16
Edge between sidewall and backing 18
Attachment area 20
Outer case wall 22
Inner case wall 24
Outer sidewall 26
Inner sidewall 28
Outer body wall 30
Inner body wall 32
AM component 34
AM case 36
AM body 38
AM sidewall 40

### Non-AM Case 42

Non-AM body 44
Non-AM sidewall 46
Raised AM portions 48
Inner AM component 50
Structural support 52

### Electroluminescent ink 54

AM Component pocket 56
Conductive ink (circuit printing) 58
Outer AM component 60
Heat sink 62
Tactile grip portion 64
Structural support 66
Aesthetic component 68
Clear coating (e.g. protect aesthetic component or electroluminescent ink) 70
Camera add-on module 72
Camera mechanical attachment component 74
Mechanical attachment device 76 (inside case)
Magnetic portion (in case) 78

### Magnet 80

### Stand 82

Stand attachment device 84
Case configured for stand attachment 86

### Circuit 88

### Antenna 90

Hybrid case 92
Multi-characteristic AM case/wall 94 (e.g. different AM processes, same materials to create different characteristics)
Multi-material case/wall 96 (e.g. different materials and/or AM processes to create different characteristics)
Anodizable material 98
High strength material 100
Thermal conducting material/high thermal conductivity material 102

### Machinable 138

Non-AM deposited layer 136 (e.g. aerosol deposition, clear coat)
Distinct layers (different layers of material) 104
Gradient layers 106
Localized different AM material or material (e.g. distinct AM regions of material) 108 (e.g. high strength, ferritic, machineable, magnetic, conductive ink, electroluminescent)
Embedded non-AM components 110 (e.g. a screen 112, a structural support 114, a graphite sheet 116)
(i.e. embedded into the case via the AM build process)

### Stand 118

### Feed 120

### AM Layer 1 122

AM Layer 2 122′ (different AM parameters, same feedstock AM layer 1 vs. 2)
Material 1 122 (e.g. alloy 1)
Material 2 124 (e.g. alloy 2)

### AM Layer A 122

### Transition A-B128

### AM Layer B 124

### Transition B-C 130

### AM Layer C 126

Consumer electronic device components:

### Chip 140

Power source (e.g. battery) 142
Sim card 144
Ear buds/headphones 146

### Display/screen 148

Logo/pattern (e.g. configured from electroluminescent ink) 132
Feed stock 134

We claim:

1. A consumer electronics case, comprising:
(a) a body;
(b) at least one sidewall attached to and extending perimetrically around the body to define an inner case wall and an outer case wall; and
(c) an additively manufactured feature on the body.

2. The consumer electronics case of claim 1, wherein the additively manufactured feature is disposed on the inner case wall.

3. The consumer electronics case of claim 2, wherein, the additively manufactured feature is selected from the group consisting of:
(a) a structural support;
(b) an electroluminescent ink;
(c) a conductive ink;
(d) a component pocket; and
(e) combinations thereof.

4. The consumer electronics case of claim 1, wherein the additively manufactured feature is disposed on the outer case wall.

5. The consumer electronics case of claim 4, wherein, the additively manufactured feature disposed on the outer case wall is selected from the group consisting of:
(a) a structural support;
(b) a heat sink;
(c) a tactile grip portion;
(d) an aesthetic component;
(e) a stand;
(f) an attachment device;
(g) an audio outlet portion;
(h) a device accessories attachment area;
(i) an integrated receptacle; and
(j) combinations thereof.

6. The consumer electronics case of claim 1, wherein the additively manufactured feature comprises a metallic additively manufactured material.

7. The consumer electronics case of claim 6, wherein the metallic additively manufactured material is selected from the group consisting of:
(a) a finishable material;
(b) a high strength material;
(c) a thermally conductive material;
(d) a machineable material; and
(e) combinations thereof.

8. The consumer electronics case of claim 7, wherein the finishable material comprises:
an aesthetic visual observation surface, a scratch resistant surface, a corrosion resistant surface, a surface durable to UV, and combinations thereof.

9. The consumer electronics case of claim 7, wherein the finishable material comprises an anodizable material configured to provide a surface of the additively manufactured feature ranging from a highly polished finish to a matte finish.

10. The consumer electronics case of claim 9, wherein the anodizable material extends along at least a portion of the inner case wall, such that, via the anodizable material, the consumer electronics case is configured with an electrically insulating substrate or an electrically insulating surface to configure additional electrical components thereon.

11. The consumer electronics case of claim 9, wherein the finishable material is selected from the group consisting of:
(a) a high purity aluminum alloy;
(b) a 7xxx series aluminum alloy;
(c) a 6xxx series aluminum alloy; and
(d) a 5xxx series aluminum alloy.

12. The consumer electronics case of claim 7, wherein the machineable material is selected from the group consisting of:
(a) a 2xxx series aluminum alloy;
(b) a 3xxx series aluminum alloy;
(c) a 5xxx series aluminum alloy;
(d) a 6xxx series aluminum alloy; and
(e) a 7xxx series aluminum alloy.

13. The consumer electronics case of claim 7, wherein the high strength material is selected from the group consisting of:
(a) a titanium alloy;
(b) a 7xxx series aluminum alloy;
(c) an Al—Li alloy;
(d) a dispersion strengthened alloy; and
(e) an aluminum based metal matrix composite.

14. The consumer electronics case of claim 1, wherein at least a portion of the body or the sidewall is additively manufactured.

15. The consumer electronics case of claim 1, wherein the additively manufactured feature is configured from a plurality of additive manufacturing feedstocks, wherein the additively manufactured feature comprises distinct additively manufactured layers or distinct additively manufactured regions.

16. The consumer electronics case of claim 15, wherein the additive manufacturing feedstock is selected from the group consisting of:
(a) an aluminum alloy;
(b) a magnesium alloy;
(c) a titanium alloy; and
(d) combinations thereof.

17. The consumer electronics case of claim 1, wherein the additively manufactured feature is configured from a plurality of additively manufactured layers or plurality of additively manufactured regions configured as a gradient from a first layer to a second layer.

18. The consumer electronics case of claim 1, wherein the additively manufactured feature is a localized portion.

19. A consumer electronics case comprising:
(a) a body;
(b) at least one sidewall attached to and extending perimetrically around the body to define an inner case wall and an outer case wall, wherein the inner case wall comprises an inner cavity configured to house a plurality of electronic components;
(c) a flexible OLED display extending across the inner cavity and communicating with the plurality of electronic components; and
(d) an additively manufactured feature configured on the inner case wall;
wherein the additively manufactured feature comprises a metallic material, and wherein the additively manufactured feature comprises a plurality of additively manufactured builds along the consumer electronics case to provide mechanical attachment of the flexible OLED to the consumer electronics case while permitting the flexible OLED display and corresponding inner case wall to adjust within threshold movement parameters.

20. A consumer electronics case comprising:
(a) a body;
(b) at least one sidewall attached to and extending perimetrically around the body to define an inner case wall and an outer case wall, wherein the inner case wall is configured to define an inner cavity to house a plurality of electronic components;
(c) at least one hole defined in the body and extending from the inner case wall to the outer case wall;
(d) a coating configured on the outer case wall and extending across the hole defined in the body; and
(e) a first additively manufactured feature configured on the inner case wall from the metallic material;
wherein the first additively manufactured feature is an electroluminescent ink that is additively deposited in the hole along an inner surface of the coating;
(f) a second additively manufactured feature on the inner case wall configured as a conductive ink configured between the electroluminescent ink and a power source; and
(g) an electrical insulator positioned between the inner case wall and the conductive ink.
